(19) United States
(12) Patent Application Publication
(10) Pub. No.: US 2011/0204753 A1
(43) Pub. Date: Aug. 25, 2011

(54) PIEZOELECTRIC DEVICE AND MANUFACTURING METHOD THEREOF

(75) Inventors: KENICHI KIKUCHI, Saitama (JP); MASAHIRO YOSHIMATSU, Saitama (JP)

(73) Assignee: NIHON DEMPA KOGYO CO., LTD., Saitama (JP)

(21) Appl. No.: 13/030,726

(22) Filed: Feb. 18, 2011

(30) Foreign Application Priority Data
Feb. 22, 2010 (JP) 2010-035870
Mar. 30, 2010 (JP) 2010-078207
Dec. 1, 2010 (JP) 2010-268518

(51) Int. Cl. H01L 41/053; H01L 41/22

(52) U.S. Cl. 310/348; 29/25.35

(57) ABSTRACT

A piezoelectric device and a manufacturing method thereof are provided. The piezoelectric device having a piezoelectric vibration sheet (130) vibrated by applying a voltage includes a first plate (110), constructing a part of the package of the piezoelectric device and having a first bonding area (112) including a frame-shaped first bonding surface (113) at outer periphery; a second plate (120), constructing a part of the package of the piezoelectric device and having a second bonding area (122) including a second bonding surface (123) corresponding to the first bonding surface; and a frame-shaped bonding material (150), formed on the two bonding surfaces and bonding the first plate and the second plate. A frame-shaped trough concave from the first bonding surface or the second bonding surface is configured in at least one of the first bonding area of the first plate or the second bonding area of the second plate.

### CROSS-REFERENCE TO RELATED APPLICATION

This application claims the priority benefits of Japanese patent application serial no. 2010-035870, filed on Feb. 22, 2010, Japanese application serial no. 2010-078207, filed on Mar. 30, 2010 and Japanese application serial no. 2010-268518, filed on Dec. 1, 2010. The entirety of each of the above-mentioned patent applications is hereby incorporated by reference herein and made a part of specification.

### BACKGROUND

1. Field of the Invention

The invention relates to a piezoelectric device formed by bonding wafers through a bonding material, and a manufacturing method thereof.

2. Description of Related Art

(Background of the Invention)

A piezoelectric device, for example, a crystal oscillator is known as a frequency control device and a selection device, and the piezoelectric device, as an indispensable element, is widely applied in civil-use digital control equipments including various communication equipments. In recent years, with the increasing demand, the piezoelectric devices with imprecise specifications, for example, a crystal oscillator with a base substrate made of ceramic or glass, are required to provide a lower price.

(Referring to an Embodiment of the Related Art, a Patent Document 1 and a Patent Document 2)

FIG. 22(a)-FIG. 22(c) are diagrams used for describing the related art, wherein FIG. 22(a) is a cross-sectional view of a crystal oscillator, FIG. 22(b) is a plane view diagram of a base substrate, and FIG. 22(c) is a plane view diagram of a crystal vibration sheet.

In the crystal oscillator, a first plate and a second plate both made of glass and respectively having a rectangular shape observed from a plane view are bonded to form a package, wherein the bonding process is for bonding a first bonding surface formed on the first plate with a second bonding surface formed on the second plate through a bonding material. Regarding the crystal oscillator shown in FIG. 22(a)-FIG. 22(c), a base substrate 1 serving as the first plate and a cover 2 serving as the second plate are bonded to form a package 3, and a crystal vibration sheet 4 serving as the piezoelectric vibration sheet is sealed in the package 3. Herein, the base substrate 1 is plate-like, and the cover 2 has a concavity (a concave cover). A pair of connection electrodes 5 is disposed at one side of an inner bottom surface of the base substrate 1, and a frame-shaped metal film 6a is formed on the first bonding surface at the outer periphery of the inner bottom surface. Installing terminals 7 used for surface installation are formed at two sides of an outer bottom surface of the base substrate 1.

Moreover, the pair of connection electrodes 5 is electrically connected to the installing terminals 7 on the outer bottom surface via the through-electrodes 8 of the base substrate 1. The through-electrode 8 is formed by filling metal into a through-hole to form an airtight state. For example, Au is printed on a Cr substrate to form a circuit pattern as described above. Since the base substrate 1 is a plate-like structure, the circuit pattern is easily formed thereon compared to a situation that the base substrate 1 is concave, shaped by etching.

The crystal vibration sheet 4 is, for example, an AT-cut crystal vibration sheet, and the crystal vibration sheet 4 includes excitation electrodes 4a at two main surfaces. Further, protrusion electrodes 4b are formed at two sides of an end portion of the crystal vibration sheet 4. The two sides of the end portion of the crystal vibration sheet 4 having the protrusion electrodes 4b are electrically and mechanically fixed to the connection electrode 5 on the inner bottom surface through a conductive adhesive 9. Moreover, the second bonding surface at an opening end surface of the concave cover 2 has a frame-shaped metal film 6b corresponding to the metal film of the base substrate 1.

Moreover, after the crystal vibration sheet 4 is fixed to the base substrate 1, a bonding material of a eutectic alloy 10, such as SuSn or AuGe, used for bonding the base substrate 1 and the concave cover 2 is applied to bond the frame-shaped metal films on the first bonding surface at the outer periphery of the base substrate 1 and on the second bonding surface at the opening end surface of the concave cover 2. In this case, a preformed frame-shaped eutectic alloy 10 is welded, for example, to the frame-shaped metal film 6a of the base substrate 1. Alternatively, the eutectic alloy 10 can be formed on the frame-shaped metal film 6a through paste printing or plating, etc. Moreover, a spherical eutectic alloy can be fixed to four corners of the frame-shaped metal film 6a (referring to a patent document 3 and a patent document 4).

Accordingly, the base substrate 1 and the frame-shaped metal film 6b of the concave cover 2 are bonded through re-melting of the eutectic alloy 10. Moreover, in the case that the eutectic alloy 10 has a ball shape and is disposed at the four corners, the eutectic alloy 10, when it is melted, is spread to the surface of the frame-shaped metal film on each side from the four corners. Therefore, since the melted metal of the eutectic alloy 10 is fully distributed on a bonding interface between the base substrate 1 and the concave cover 2, the two parts are bonded. Then, the concave cover 2 is bonded to the base substrate 1 to form the package 3 having the sealed crystal vibration sheet 4, i.e. to form the crystal oscillator for surface mounting.

According to the above descriptions, a manufacturing method of the crystal oscillator capable of improving productivity thereof is provided with reference of FIG. 23(a) and FIG. 23(b). First, the base substrates 1 and the concave covers 2 are arranged in an array to integrally form a single base substrate wafer 1A and a concave cover wafer 2A. FIG. 23(a) is a plane diagram of the base substrate wafer 1A, and FIG. 23(b) is a plane view diagram of an opening end surface side of the concave cover wafer 2A.

Moreover, after the crystal vibration sheet 4 is fixed to the connection electrode 5 of the base substrate wafer 1A, the eutectic alloy 10 is used to bond the concave cover wafer 2A to form a package wafer (a crystal oscillator wafer). Then, the package wafer is diced into the packages 3 along the vertical and horizontal A-A line and B-B line to obtain a plurality of crystal oscillators. In this example, the frame-shaped metal film 6a and the frame-shaped metal film 6b are separately formed on the outer periphery surfaces of the base substrate wafer 1A and the concave cover wafer 2A. In this way, since the glass material is exposed, it is easy to be diced.

### DOCUMENTS OF THE RELATED ART

### Patent Documents

[Patent document 1] Japan Patent No. 3621425
[Patent document 2] Japan Patent special-open No. 2009-194091
[Patent document 3] International Patent Publication No. WO2008/140033
[Patent document 4] Japan Patent No. 2009-213926

### PROBLEMS OF THE RELATED ART

However, regarding the aforementioned crystal oscillator (the manufacturing method thereof), when the base substrate wafer 1A and the concave cover wafer 2A are bonded, for example, the base substrate wafer 1A is located at the lower side, and the concave cover wafer 2A is located at the upper side, the base substrate wafer 1A and the concave cover wafer 2A are oppositely abutted (positioned). In this case, since the plane shape of the base substrate wafer 1A and the concave cover wafer 2A is enlarged, strain is generated on the plates, so that a gap is formed between the plates due to warpage (bending) of the plates. Therefore, as shown in FIG. 24(a), by pressing the concave cover wafer 2A (along an arrow direction), the warpage of the base substrate wafer 1A and the concave cover wafer 2A are corrected to prevent poor bonding (poor sealing).

However, since the concave cover wafer 2A is pressed, the melted metal of the eutectic alloy 10 is overflowed from the junction between the frame-shaped metal film 6a and the frame-shaped metal film 6b (shown in FIG. 24(b)), and contact the connection electrode 5 or the crystal vibration sheet 4; alternatively, the overflowed eutectic alloy 10 falls off due to impact and is scattered in the package, which may influence a vibration property of the crystal oscillator. Moreover, FIG. 24(a) is a cross-sectional view of the base substrate wafer 1A and the concave cover wafer 2A, and FIG. 24(b) is a partial enlarged cross-sectional view of a dot line frame represented by a symbol of [symbol] . Moreover, C-C is a cut line along a thickness direction.

### SUMMARY OF THE INVENTION

### A Purpose of the Invention

The invention is directed to a piezoelectric device in which an overflow of a bonding material is prevented for maintaining the vibration property of the device, and a manufacturing method thereof.

A piezoelectric device of a 1^{st} aspect having a piezoelectric vibration sheet vibrated by applying a voltage includes a first plate, forming a part of the package of the piezoelectric device and having a first bonding area that includes a frame-shaped first bonding surface at an outer periphery; a second plate, forming a part of the package of the piezoelectric device and having a second bonding area that includes a second bonding surface corresponding to the first bonding surface; and a frame-shaped bonding material, formed on the first bonding surface and the second bonding surface, and bonding the first plate and the second plate. Further, a frame-shaped trough concave from the first bonding surface or the second bonding surface is configured in at least one of the first bonding area of the first plate and the second bonding area of the second plate.

A piezoelectric device of a 2^{nd} aspect having a piezoelectric vibration sheet vibrated by applying a voltage includes a first plate, forming a part of the package of the piezoelectric device and having a first bonding area that includes a frame-shaped first bonding surface at an outer periphery; a second plate, forming a part of the package of the piezoelectric device and having a second bonding area that includes a frame-shaped second bonding surface at an outer periphery; a third plate, composed of the piezoelectric vibration sheet and a frame enclosing the piezoelectric vibration sheet, where the frame has a third bonding area that includes a third bonding surface corresponding to the first bonding surface and a fourth bonding area that includes a fourth bonding surface located at an opposite side of the third bonding surface and corresponding to the second bonding surface; and a frame-shaped bonding material, formed on the first bonding surface, the second bonding surface, the third bonding surface, and the fourth bonding surface, and bonding the first plate and the third plate, and bonding the second plate and the fourth plate. Further, a frame-shaped trough concave from the first bonding surface, the second bonding surface, the third bonding surface, or the fourth bonding surface is configured in at least one of the first bonding surface and the third bonding surface and at least one of the second bonding surface and the fourth bonding surface.

According to the 1^{st} aspect or the 2^{nd} aspect, regarding the piezoelectric device of a 3^{rd} aspect, at least a part of the bonding material enters the frame-shaped trough.

According to the 1^{st} aspect to the 3^{rd} aspect, regarding the piezoelectric device of a 4^{th} aspect, the frame-shaped trough includes a stepped portion with a sidewall formed in at least one direction, and the stepped portion is formed at the outermost periphery of the piezoelectric device.

According to the 1^{st} aspect to the 3^{rd} aspect, regarding the piezoelectric device of a 5^{th} aspect, the frame-shaped trough includes a plurality of troughs, and the troughs are formed at an inner side of the frame-shaped bonding material and at a bonding surface side of the bonding material.

According to the 1^{st} aspect to the 5^{th} aspect, regarding the piezoelectric device of a 6^{th} aspect, a frame-shaped metal film is formed under the bonding material, and the bonding material is a eutectic alloy.

According to the 6^{th} aspect, regarding the piezoelectric device of a 7^{th} aspect, the frame-shaped metal film is formed on an inner bottom surface of the frame-shaped trough. Accordingly, since melted metal of an eutectic alloy is accumulated in the frame-shaped trough, the melted metal is prevented from flowing from a frame surface of the frame-shaped trough to a more internal part of the piezoelectric device.

According to the 7^{th} aspect, regarding the piezoelectric device of an 8^{th} aspect, a width of the frame-shaped metal film is narrower than a width of the frame-shaped trough. Accordingly, since the melted metal of the eutectic alloy between the frame-shaped metal films is accumulated in the frame-shaped trough along a width direction, an overflow of the melted metal can be further prevented.

According to the 8^{th} aspect, regarding the piezoelectric device of a 9^{th} aspect, the frame-shaped trough is disposed in at least an inner side of the frame-shaped metal film. Accordingly, since the melted metal of the eutectic alloy between the frame-shaped metal films flows towards the frame-shaped trough, it prevents the melted metal from flowing to the more internal part of the piezoelectric device.

According to the 9^{th} aspect, regarding the piezoelectric device of a 10^{th} aspect, a metal film is disposed on the inner bottom surface of the frame-shaped trough. Accordingly, since melted metal of the eutectic alloy is adhered to the metal film, the melted metal is prevented from flowing to a more internal part of the piezoelectric device.

A manufacturing method of a piezoelectric device of the 11^{th} aspect having a piezoelectric vibration sheet vibrated by applying a voltage is provided, and the manufacturing method includes the following steps. In a first preparation step, a first wafer including a plurality of first plates is provided, wherein the first plates construct a part of a package of the piezoelectric device and have a frame-shaped first bonding surface at an outer periphery. In a second preparation step, a second wafer including a plurality of second plates is provided, wherein the second plates construct a part of the package of the piezoelectric device and have a second bonding surface corresponding to the first bonding surface. In a bonding step, a bonding material, in a shape of a frame structure, formed on the first bonding surface or the second bonding surface is used to bond the first wafer and the second wafer. In a cutting step, the bonded first wafer and the second wafer are diced by applying a scribe line, wherein at least one of the first preparation step and the second preparation step is performed and at least a part of the scribe line is included to form a frame-shaped trough concave from the first bonding surface or the second bonding surface at the outer periphery of the first plate or the second plate, and the bonding step is performed to introduce the bonding material into at least a part of the frame-shaped trough.

A manufacturing method of a piezoelectric device of the 12^{th} aspect having a piezoelectric vibration sheet vibrated by applying a voltage is provided, and the method includes the following steps. In a first preparation step, a first wafer including a plurality of first plates is provided, wherein the first plates construct a part of a package of the piezoelectric device and have a frame-shaped first bonding surface at an outer periphery. In a second preparation step, a second wafer including a plurality of second plates is provided, wherein the second plates construct a part of the package of the piezoelectric device and have a second bonding surface at an outer periphery. In a third preparation step, a third wafer including a plurality of third plates is provided, wherein the third plates include a plurality of piezoelectric vibration sheets and a plurality of frames respectively enclosing the piezoelectric vibration sheets, wherein each frame has a third bonding surface corresponding to the first bonding surface, and a fourth bonding surface located at an opposite side of the third bonding surface and corresponding to the second bonding surface. In a bonding step, a bonding material, in a shape of a frame structure, is formed on the first bonding surface, the second bonding surface, the third bonding surface or the fourth bonding surface to bond the first wafer and the second wafer with the third wafer in between. In a dicing step, the bonded first wafer, the second wafer and the third wafer are diced by applying a scribe line, wherein at least one of the first preparation step, the second preparation step, and the third preparation step is performed and at least a part of the scribe line is included to form a frame-shaped trough depressed from the first bonding surface, the second bonding surface, the third bonding surface, or the fourth bonding surface of the first plate, the second plate or the third plate, and the bonding step is performed to introduce the bonding material into at least a part of the frame-shaped trough.

According to the 11^{th} aspect or the 12^{th} aspect, regarding the manufacturing method of the piezoelectric device of a 13^{th} aspect, the frame-shaped trough includes a plurality of troughs, and the troughs are formed at an inner side of the bonding material and at a bonding surface side of the bonding material.

According to the 11^{th} aspect to the 13^{th} aspect, regarding the manufacturing method of the piezoelectric device of a 14^{th} aspect, the frame-shaped trough includes the scribe line, and a width of the frame-shaped trough including the scribe line is narrower than a width of the scribe line.

### Effect of the Invention

According to the invention, a piezoelectric device, in which an overflow of a bonding material is prevented for maintaining the vibration property, and a manufacturing method thereof are provided.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a plane view diagram of a base substrate wafer divided into four parts according to a first embodiment of the invention.

FIG. 2 is a plane view diagram of an opening end surface side of a concave cover wafer divided into four parts according to the first embodiment of the invention.

FIG. 3(a)-FIG. 3(c) are diagrams illustrating the bonding states of a base substrate wafer and a concave cover wafer according to the first embodiment of the invention, where FIG. 3(a) is an exploded cross-sectional view of the base substrate wafer and the concave cover wafer, FIG. 3(b) is a partial enlarged cross-sectional view of a dot line frame represented by a symbol of [symbol] , and FIG. 3(c) is a partial enlarged cross-sectional view after positioning.

FIG. 4(a)-FIG. 4(b) are diagrams illustrating the bonding states of a base substrate wafer and a concave cover wafer according to other examples of the first embodiment of the invention, where FIG. 4(a) and FIG. 4(b) are all partial enlarged cross-sectional views.

FIG. 5(a)-FIG. 5(b) are diagrams illustrating the bonding states of a base substrate wafer and a concave cover wafer according to a second embodiment of the invention, where FIG. 5(a) and FIG. 5(b) are all partial enlarged cross-sectional views.

FIG. 6(a)-FIG. 6(b) are diagrams illustrating the bonding states of a base substrate wafer and a concave cover wafer according to other examples of the second embodiment of the invention, where FIG. 6(a) and FIG. 6(b) are all partial enlarged cross-sectional views.

FIG. 7(a) is an exploded three-dimensional view of a piezoelectric device 100.

FIG. 7(b) is a cross-sectional view of FIG. 7(a) along a D-D line.

FIG. 8 is a flowchart illustrating a manufacturing method of the piezoelectric device 100.

FIG. 9 is a plane view diagram of a first wafer W110.

FIG. 10 is a plane view diagram of a second wafer W120.

FIG. 11(a)-FIG. 11(d) are flowcharts for describing a process of a step S104 of FIG. 8, where a piezoelectric vibration sheet 130 is disposed on a second wafer W120 and a first wafer W110 is bonded to the second wafer W120.

FIG. 12 is a cross-sectional view of a piezoelectric device 100 formed by the dicing operation when a width of a scribe line is wider than a total width 2-s of adjacent frame-shaped troughs 126.

FIG. 13 (a) is an enlarged schematic cross-sectional view of a part of FIG. 11(b) encircled by a dot line 170.

FIG. 13(b) is an enlarged schematic cross-sectional view of a second wafer W120′ without a frame-shaped trough 126.

FIG. 14(a) is a cross-sectional view of a piezoelectric device 200.

FIG. 14(b) is a schematic cross-sectional view of a first wafer W110 and a second wafer W220 before bonding.

FIG. 14(c) is a schematic cross-sectional view of the first wafer W110 and the second wafer W220 formed with a plurality of the second plates 220 after bonding.

FIG. 15 is an exploded three-dimensional view of a piezoelectric device 300.

FIG. 16 is a cross-sectional view of FIG. 15 along a F-F line

FIG. 17 is a flowchart illustrating a manufacturing method of the piezoelectric device 300.

FIG. 18 is a plane view diagram of a first wafer W310.

FIG. 19 is a plane view diagram of the second wafer W320.

FIG. 20 is a plane view diagram of the third wafer W330.

FIG. 21(a)-FIG. 21(d) are flowcharts for describing a bonding process of a step S204 of FIG. 17, where the first wafer W310, the second wafer W320 and the third wafer W330 are bonded.

FIG. 22(a)-FIG. 22(c) are diagrams used for describing the related art, where FIG. 22(a) is a cross-sectional view of a crystal oscillator, FIG. 22(b) is a plane view diagram of a base substrate, and FIG. 22(c) is a plane view diagram of a crystal vibration sheet.

FIG. 23(a)-FIG. 23(b) are diagrams used for describing the related art, where FIG. 23(a) is a plane view diagram of a base substrate wafer, and FIG. 23(b) is a plane view diagram of an opening end surface side of a concave cover wafer.

FIG. 24(a)-FIG. 24(b) are diagrams illustrating the bonding states of a base substrate wafer and a concave cover wafer used for describing the related art, wherein FIG. 24(a) is a whole cross-sectional view, and FIG. 24(b) is a partial enlarged cross-sectional view of a dot line frame represented by a symbol of “ [symbol] ”.

### DETAILED DESCRIPTION OF DISCLOSED EMBODIMENTS

### First Embodiment

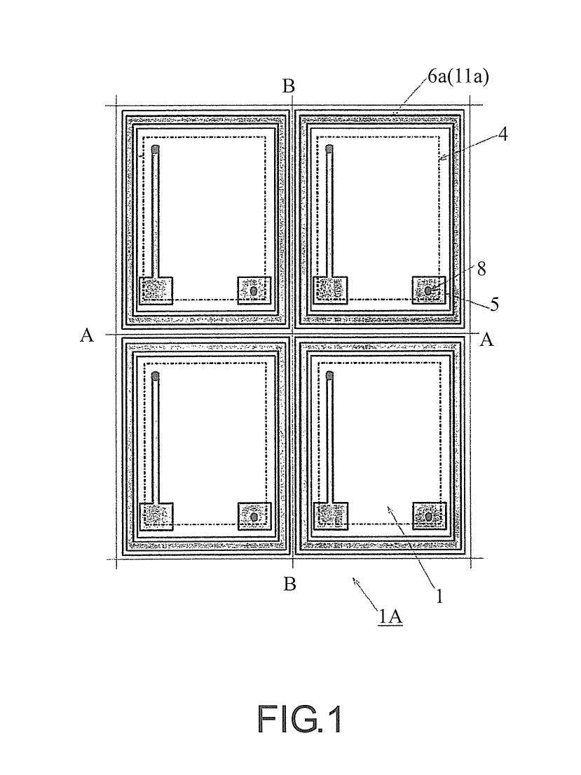

The first embodiment of the invention is described according to a manufacturing method and FIG. 1 to FIG. 4(a) and FIG. 4(b). Moreover, the same reference numbers are used in the first embodiment and the related art to refer to the same or like elements, and the description thereof are either simplified or omitted.

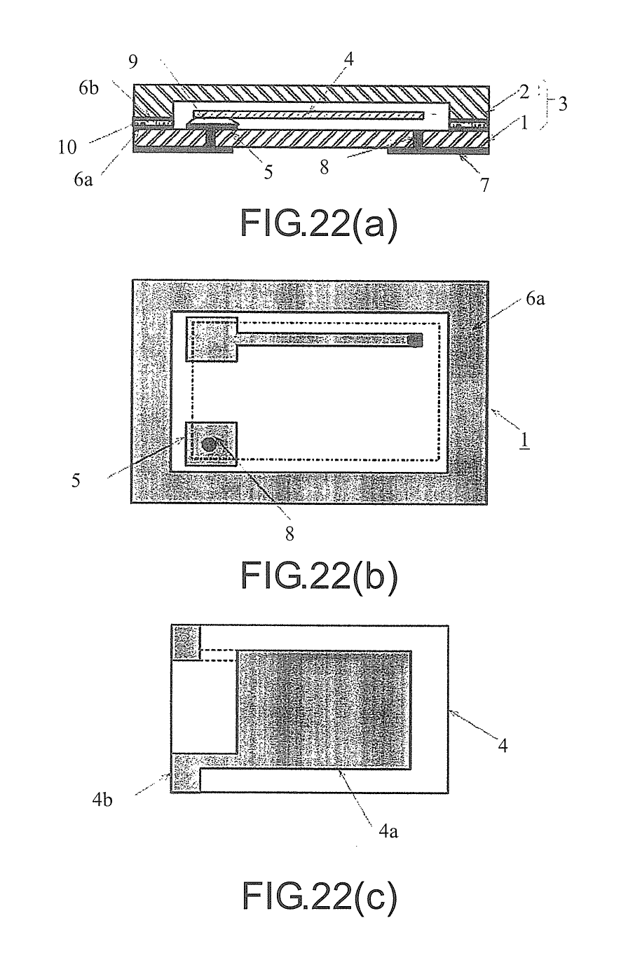

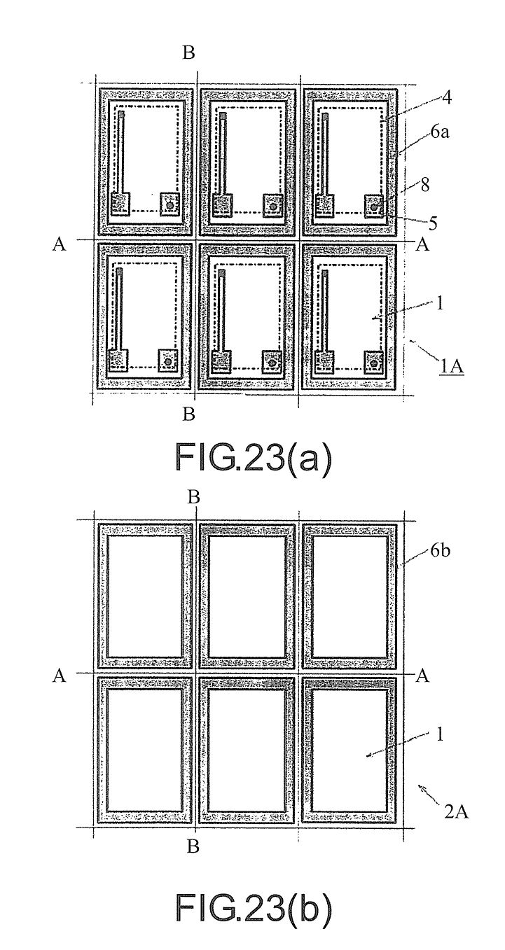

As described in the related art, in the crystal oscillator, the plate-shaped first plate, i.e. the base substrate 1 made of glass and having a rectangular shape observed from a plane view and including the connection electrodes 5 and the frame-shaped metal film 6a, and the second plate, i.e. the concave cover 2 made of glass and including the frame-shaped metal film 6b at the opening end surface are bonded to form the package 3, and the crystal vibration sheet 4 including the excitation electrodes 4a and the protrusion electrodes 4b is sealed in the package 3. The two sides of the end portion of the crystal vibration sheet 4 having the protrusion electrodes 4b are fixed to the connection electrodes 5 through the conductive adhesive 9. Moreover, the frame-shaped metal film 6a and the frame-shaped metal film 6b between the base substrate 1 and the concave cover 2 are bonded via the melting of the eutectic alloy 10, and the crystal vibration sheet 4 is sealed in the package 3 (referring to FIG. 22(a)-FIG. 22(c)).

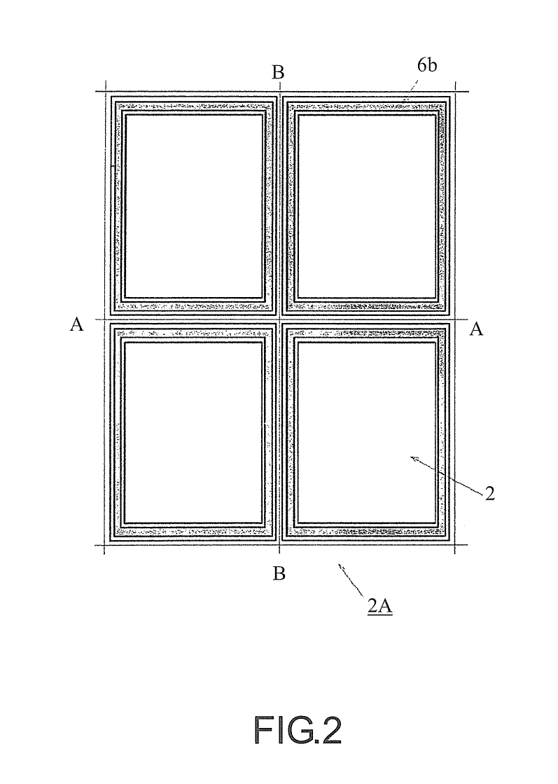

In the present embodiment, similar to the above description, the base substrates 1 (FIG. 1) and the concave covers 2 (FIG. 2) are arranged in an array to form a single base substrate wafer 1A and a concave cover wafer 2A. Outer periphery surfaces of the rectangular regions of the base substrates 1 and the concave covers 2 on the base substrate wafer 1A and the concave cover wafer 2A respectively include the frame-shaped metal films 6a and the frame-shaped metal films 6b disposed opposite to each other. The frame-shaped metal films 6a of the base substrate wafer 1A and the frame-shaped metal films 6b of the concave cover wafer 2A are separated from each other in the gap between the adjacent rectangular regions, and the glass material is exposed through the gap between the rectangular regions.

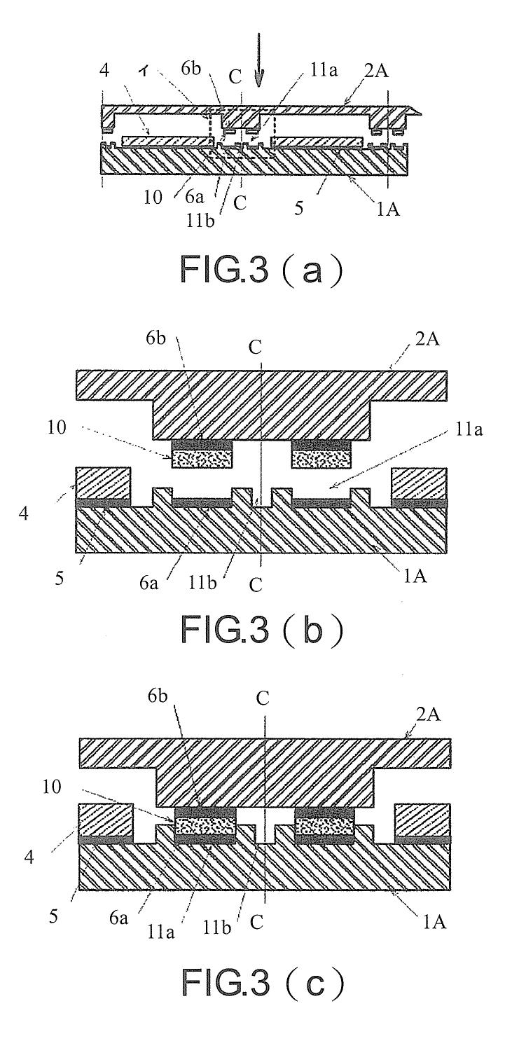

Here, the outer peripheral surface of each rectangular region of the base substrate wafer 1A includes a frame-shaped trough 11a, and a frame-shaped metal film 6a is configured on an inner bottom surface of the frame-shaped trough 11a. Moreover, the frame-shaped troughs 11a of the adjacent rectangular regions are separated by the same frame-shaped trough 11b (referring to FIG. 3(a)-FIG. 3(c)). The frame-shaped metal film 6b formed on the outer peripheral surface (the opening end surface) of each rectangular region of the concave cover wafer 2A is formed at a central portion of the opening end surface separated from the periphery and inner periphery thereof. Moreover, the frame-shaped trough 11a and the frame-shaped metal film 6a and the frame-shaped metal film 6b substantially have a same width. In addition, two sides of an end portion of each rectangular region of the base substrate wafer 1A include connection electrodes 5, and the connection electrodes 5 and the two sides of the end portion of each rectangular region of the base substrate wafer 1A are electrically connected through the installing terminal 7 disposed at the outer bottom surface and the through-electrode 8 (referring to FIG. 22(a)-FIG. 22(c)).

Regarding the aforementioned members, as shown in FIG. 3(a) and FIG. 3(b), a bonding material of eutectic alloy 10, such as AuSn or AuGe, etc., is coated on the frame-shaped metal film 6b of the opening end surface of the concave cover wafer 2A. First, the opening end surface (the outer periphery surface) of the concave cover wafer 2A formed with the frame-shaped metal film 6a and the frame-shaped metal film 6b is positioned to the outer periphery surface of the base substrate wafer 1A fixed with the crystal vibration sheet 4. Then, as shown by the arrow, the concave cover wafer 2A is pressed from the top. In this way, warping of the base substrate wafer 1A and the concave cover wafer 2A is eliminated, and the outer periphery surfaces of the two wafers are abutted or approached to each other, and the eutectic alloy 10 is substantially infused in the frame-shaped troughs 11a of the base substrate wafer 1A.

Then, as shown in FIG. 3(c), as the concave cover wafer 2A is pressed, the eutectic alloy 10 is heated, and the frame-shaped metal film 6a and the frame-shaped metal film 6b between the base substrate wafer 1A and the concave cover wafer 2A are bonded as the eutectic alloy 10 is melted. In this case, the heated eutectic alloy 10 is squeezed out to two protrusions at two sides of the frame-shaped trough 11a due to the pressing from the top of the concave cover wafer 2A, although most of the melted metal is aggregated in the frame-shaped trough 11a.

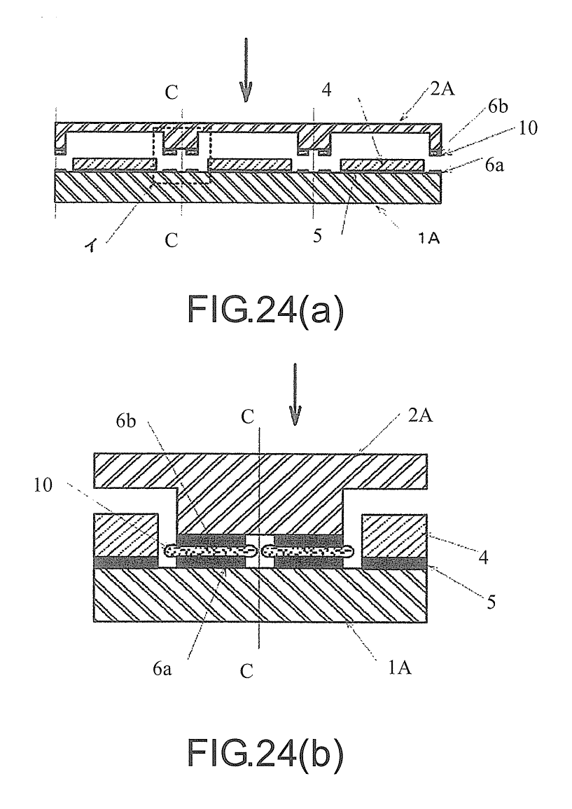

Therefore, compared to the embodiment of the related art (FIG. 24(a) and FIG. 24(b)) that the outer periphery surfaces of the base substrate wafer 1A and the concave cover wafer 2 are all flat and the entire periphery surfaces are pressed, the amount of the melted metal overflows from the interface of the base substrate wafer 1A and the concave cover wafer 2 is reduced. Therefore, the problem of the overflowed eutectic alloy 10 (melted metal) being in contact with the crystal vibration sheet 4 or the connection electrode 5 can be avoided, and the vibration property is thereby maintained.

Finally, the bonded package wafer is divided into multiple crystal oscillators along the horizontal and vertical cut lines A-A and B-B and along a cut line C-C in a thickness direction. For example, a dicing saw is used for the dicing operation, and the blade width of the dicing saw is consistent with the width of the frame-shape trough 11b between the adjacent rectangular regions. In this case, since the overflow of the eutectic alloy 10 to the frame-shaped trough 11b between the adjacent frame-shaped troughs 11a of the base substrate wafer 11A is suppressed, the dicing operation is easily performed. However, since the amount of the overflow is reduced, the frame-shaped trough can also be omitted.

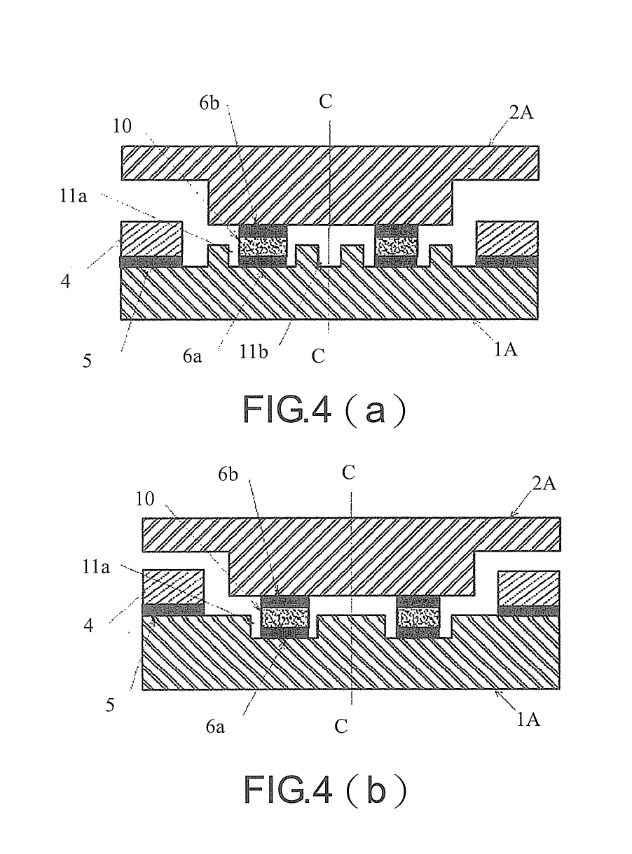

Moreover, in the above embodiment, the frame-shaped trough 11a of the base substrate wafer 1A, the frame-shaped metal film 6a and the frame-shaped metal film 6b have the same width, although as shown in FIG. 4(a), the width of the frame-shaped metal film 6a of the base substrate wafer 1A is narrower than the width of the frame-shaped trough 11a. Herein, the width of the frame-shaped metal film 6b of the concave cover wafer 2A is also narrower than the width of the frame-shaped trough 11a. Accordingly, the frame-shaped metal film 6a and the frame-shaped metal film 6b are separated from the inner periphery of the frame-shaped trough 11a to form a gap therebetween. Therefore, when the eutectic alloy 10 is melted as the concave cover wafer 2A is pressed, the melted metal of the eutectic alloy 10 squeezed out to the gap between the frame-shaped metal films 6a and 6b and the inner periphery of the frame-shaped trough 11a and an overflow to the outside of the frame-shaped trough 11a can be further suppressed.

Further, the frame-shaped trough 11a is formed by forming extended structures protruded from the surface at two sides, though as shown in FIG. 4(b), the extended structure of the inner side can also be an inner bottom surface fixed with the crystal vibration sheet 4. Moreover, since the overflow amount of the eutectic alloy 10 is reduced, the frame-shaped trough 11b can also be omitted to provide a planar surface.

### Second Embodiment

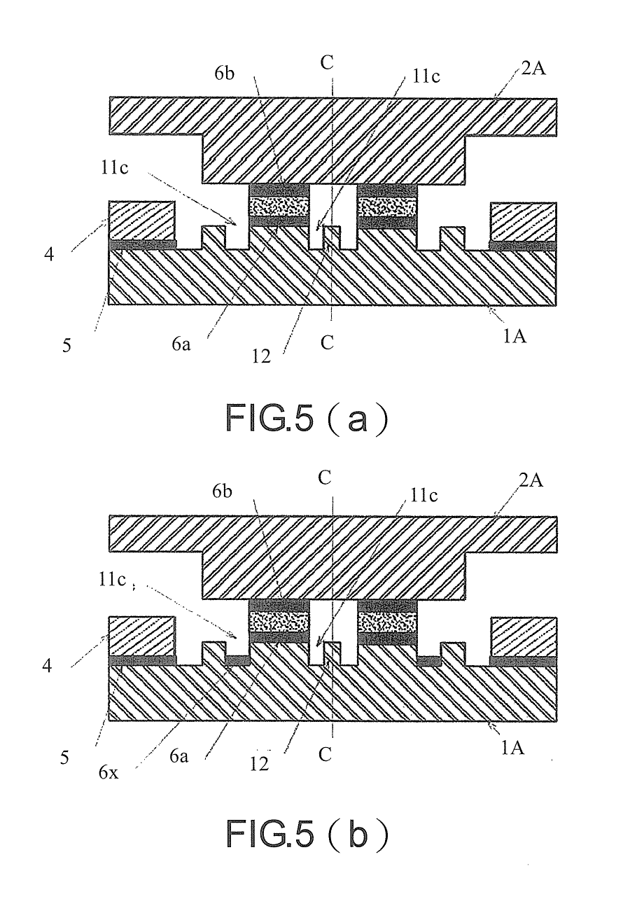

In the second embodiment, for example, as shown by a partial enlarged diagram of FIG. 5(a), the outer periphery of the base substrate wafer 1A formed with the frame-shaped film 6a is as follows. Namely, frame-shaped troughs 11c are disposed at two sides of the frame-shaped metal film 6a. Moreover, the frame-shaped troughs 11c are independent between the adjacent rectangular regions due to an extended structure 12. Therefore, when the eutectic alloy 10 is heated as the concave cover wafer 2A is pressed, even if the melted metal overflows to the two sides due to the pressing, it flows into the frame-shaped troughs 11c. Therefore, the melted metal is prevented from flowing to the internal of the device where the crystal vibration sheet 4 is located. Further, after the wafers are bonded, the dicing can be easily performed since a surface of the extended structure 12 exposes the glass.

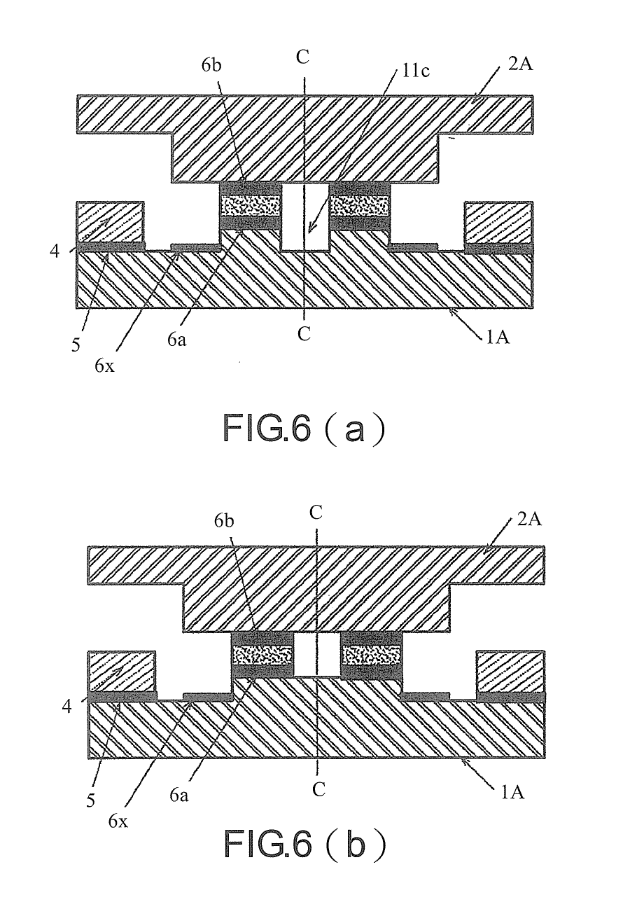

In case of the above situation, as shown in FIG. 5(b), frame-shaped metal films 6x are respectively disposed in the frame-shaped troughs 11c of the inner sides. Therefore, since the eutectic alloy 10 (melted metal) overflowed from the junction between the frame-shaped metal film 6a and the frame-shaped metal film 6b is adhered to the metal film 6x, the overflowed eutectic alloy 10 is prevented from flowing into the internal of the structure. Therefore, as shown in FIG. 6(a), the frame-shaped trough 11c located at the inner side of the frame-shaped metal film 6a is configured to be flat, and only the frame-shaped metal film 6x is disposed.

Further, although the extended structure 12 is provided to facilitate the dicing operation, since the easiness of the dicing operation depends on the dicing method, the extended structure 12 can be removed according to the design requirement. In this case, the outer frame-shaped trough 11c is configured to be flat (referring to FIG. 6(b)).

(Other Matters Need Attention)

In the above embodiment, the eutectic alloy 10 is used as the bonding material, and the eutectic alloy 10 is disposed at the opening end surface of the concave cover wafer 2A through plating. However, the invention is not limited thereto, for example, a preformed frame-shaped eutectic alloy can be welded, or formed through paste printing. Moreover, a spherical eutectic alloy can also be applied. Further, a low melting point glass or a polyimide resin, etc. can be used as the bonding material without foaming the frame-shaped metal films. Moreover, although the base substrate 1 is configured to be flat and the cover 2 is configured to be concave, it is still applicable if the base substrate 1 is configured to be concave and the cover 2 is configured to be flat. In addition, it is still applicable when the eutectic alloy 10 is set to the base substrate 1. Further, the piezoelectric device used as the crystal oscillator has been described above, though an integrated circuit (IC) chip forming an oscillating circuit together with the crystal vibration sheet 4 can also be included to form the crystal oscillator, which is applicable to the piezoelectric device including at least the piezoelectric vibration sheet. The above descriptions can also be applied to the following embodiments.

In the aforementioned embodiment, the base substrate 1 and the concave cover 2 are made of glass, where in most cases, the boron silicate glass with a price cheaper than that of the crystal is used. A Knoop hardness of the boron silicate glass is 590 kg/mm². On the other hand, a Knoop hardness of the crystal is 710 kg/mm² to 790 kg/mm², which is higher than that of the boron silicate glass. Therefore, the crystal is used to form the base substrate 1 and the concave cover 2. In this way, a structure strength is ensured, and miniaturization and low profile of the package 3 can be implemented.

### Third Embodiment

In the third embodiment, a piezoelectric device 100 is described. In the piezoelectric device 100, a concave portion is formed on the second plate serving as the base substrate, and a low melting point glass is used as the bonding material.

<Formation of the Piezoelectric Device 100>

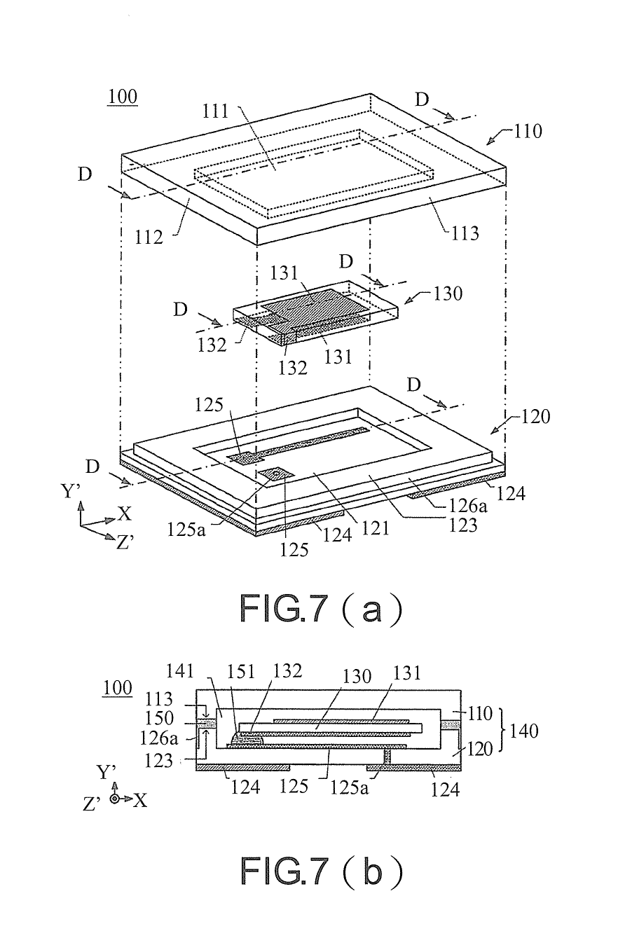

FIG. 7(a) is an exploded three-dimensional view of the piezoelectric device 100. The piezoelectric device 100 is composed of a first plate 110, a second plate 120, a piezoelectric vibration sheet 130, and a bonding material 150 (referring to FIG. 7(b)). In the piezoelectric device 100, the first plate 110 is a cover, and the second plate 120 is a base substrate. The first plate 110 and the second plate 120 are bonded to form a package 140 (referring to FIG. 7(b)). A cavity 141 (referring to FIG. 7(b)) is formed in the package 140, and the piezoelectric vibration sheet 130 is disposed in the cavity 141. For example, an AT-cut crystal vibration sheet is used as the piezoelectric vibration sheet 130. A main plane (a YZ plane) of the AT-cut crystal vibration sheet tilts 35° 15′, relative to the Y-axis of the crystal axes (XYZ) from the Z-axis with the X-axis as the center, towards a Y-axis direction. In the following descriptions, the axis directions of the AT-cut crystal vibration sheet are referred as a base and the tilt new axes are used as a Y′-axis and a Z′-axis. Namely, in the piezoelectric device 100, a longitudinal direction of the piezoelectric device 100 is set as a X-axis direction, and a height direction of the piezoelectric device 100 is set as a Y′-axis direction, and a direction perpendicular to the X-axis direction and the Y′-axis direction is set as a Z′-axis direction.

Excitation electrodes 131 are formed on surfaces of the +Y′-axis side and the −Y′-axis side of the piezoelectric vibration sheet 130. The excitation electrodes 131 are respectively connected to protrusion electrodes 132 protruding towards the −X-axis direction. The protrusion electrode 132 connected to the excitation electrode 131 formed on the surface of the +Y′-axis side extends towards the −X-axis direction from the excitation electrode 131, and extends to a surface of the −Y′-axis side through a side surface of the +Z′-axis side. The protrusion electrode 132 connected to the excitation electrode 131 formed on the surface of the −Y′-axis side extends towards the −X-axis direction on the surface of the −Y′-axis side until an end of the −Z-axis side.

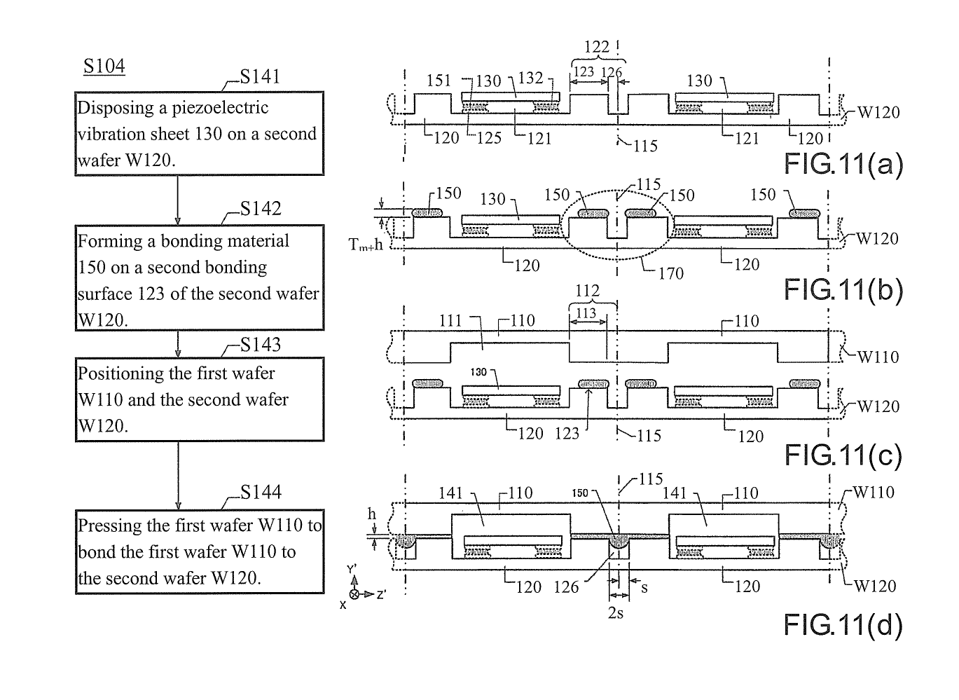

A concave portion 111 constructing a part of the cavity 141 (referring to FIG. 7(b)) is formed on the surface of the −Y′-axis side of the first plate 110. Further, a first bonding area 112 is formed to enclose, in a shape of a frame structure, the concave portion 111. In the first bonding area 112, a first bonding surface 113 used to bond a second bonding surface 123 of the second plate 120 is formed. A detailed relationship between the first bonding area 112 and the first bonding surface 113 is described hereinafter with reference of FIG. 11(a)-FIG. 11(d).

A concave portion 121 constructing a part of the cavity 141 is formed on the surface of the +Y′-axis side of the second plate 120, and the second bonding surface 123, in a shape of a frame structure, is formed to enclose the concave portion 121. Further, a stepped portion 126a is formed at an outer periphery of the second bonding surface 123. Moreover, the stepped portion 126a is a part of a frame-shaped trough 126 (referring to FIG. 11(a)-FIG. 11(d). Further, two installing terminals 124 are formed on the surface of the −Y′-axis side. Two connection electrodes 125 are formed in the concave portion 121, and the protrusion electrodes 132 of the piezoelectric vibration sheet 130 are respectively connected to the connection electrodes 125 through a conductive adhesive 151 (referring to FIG. 7(b)). Further, the connection electrodes 125 are respectively connected to the installing terminals 124 via the through-electrodes 125a penetrating through the second plate 120.

FIG. 7(b) is a cross-sectional view of FIG. 7(a) along a D-D line. The first bonding surface 113 of the first plate 110 is bonded to the second bonding surface 123 of the second plate 120 through the bonding material 150. Further, the bonding material 150 penetrates to the stepped portion 126a. The package 140 is formed by bonding the first plate 110 with the second plate 120, and the sealed cavity 141 is formed inside the package 140. Further, the piezoelectric vibration sheet 130 is located in the cavity 141. The protrusion electrodes 132 of the piezoelectric vibration sheet 130 are electrically connected to the connection electrodes 125 via the conductive adhesive 151. The connection electrodes 125 are electrically connected to the installing terminals 124 via the through-electrodes 125a penetrating through the second plate 120. Namely, the excitation electrodes 131 of the piezoelectric vibration sheet 130 are electrically connected to the installing terminals 124, and a voltage can be applied to the two installing terminals 124 to vibrate the piezoelectric vibration sheet 130.

<Manufacturing Method of the Piezoelectric Device 100>

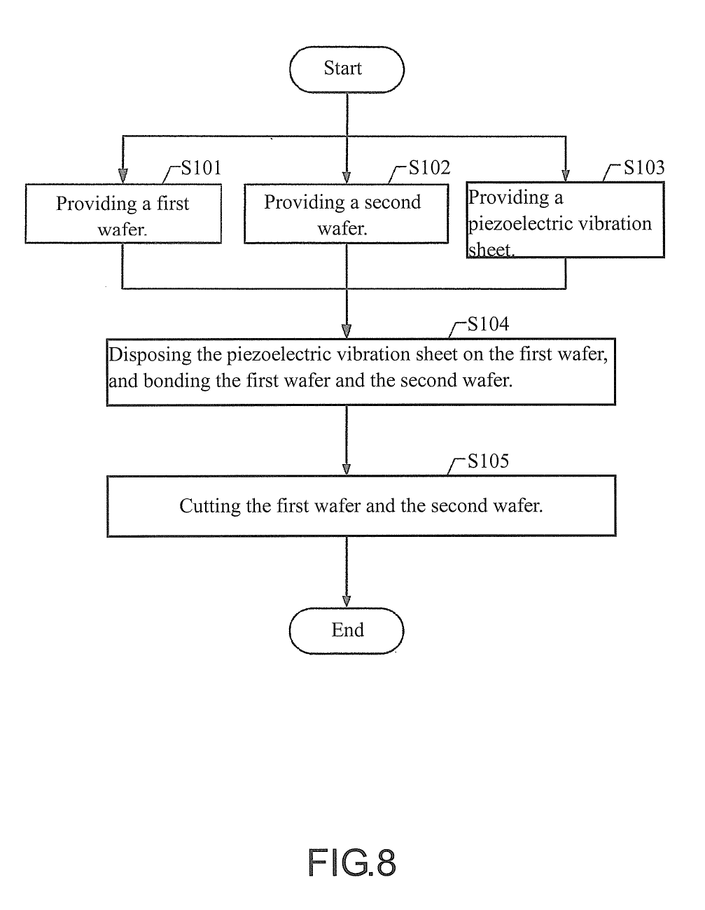

FIG. 8 is a flowchart illustrating a manufacturing method of the piezoelectric device 100.

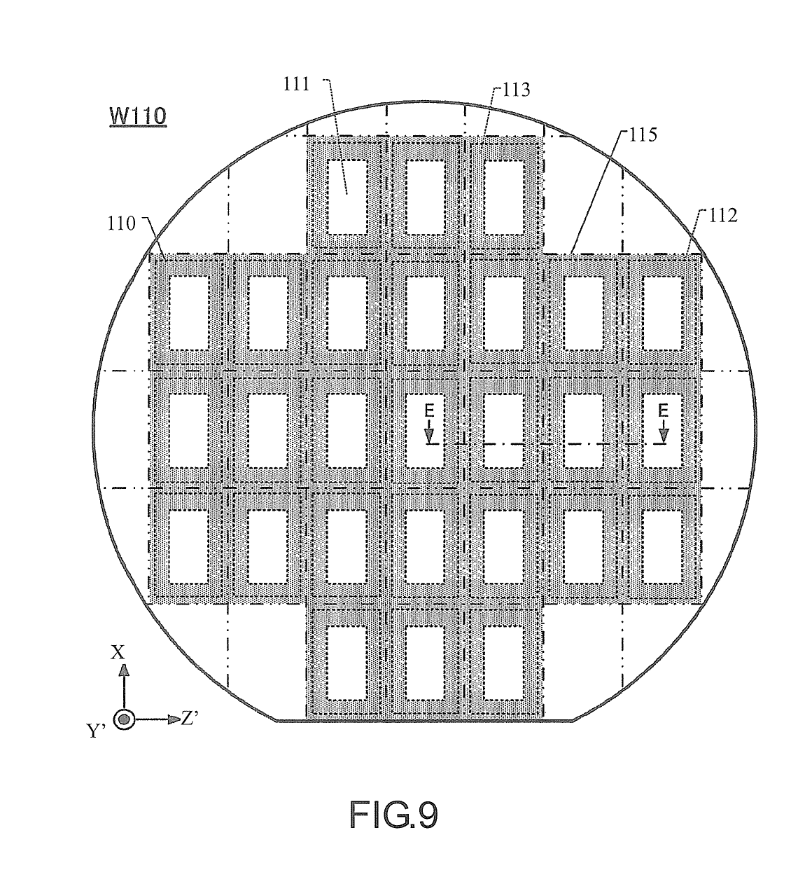

First, in step S101, a first wafer W110 is provided. A plurality of first plates 110 is formed on the first wafer W110. The first wafer W110 is, made of for example, crystal or glass, etc. Description of the first wafer W110 is provided with reference of FIG. 9.

FIG. 9 is a plane view of the first wafer W110. A plurality of the first plates 110 is formed on the first wafer W110. In FIG. 9, a boundary line of two adjacent first plates 110 is represented by a two-dot chain line. The two-dot chain line is a scribe line 115 applied in the dicing of the wafer in a step S105 of FIG. 8. The concave portion 111 is formed on the surface of each of the first plates 110 at the −Y′-axis, the first bonding area 112 is formed at the periphery of the concave portion 111, and the first bonding surface 113 is formed in the first bonding area 112. The first bonding area 112 is an area sandwiched between the scribe line 115 and the concave portion 111 (a hatched area of FIG. 9). Further, the first bonding surface 113 is a part of the first bonding area 112, which is used for bonding the second bonding surface 123 of the second plate 120.

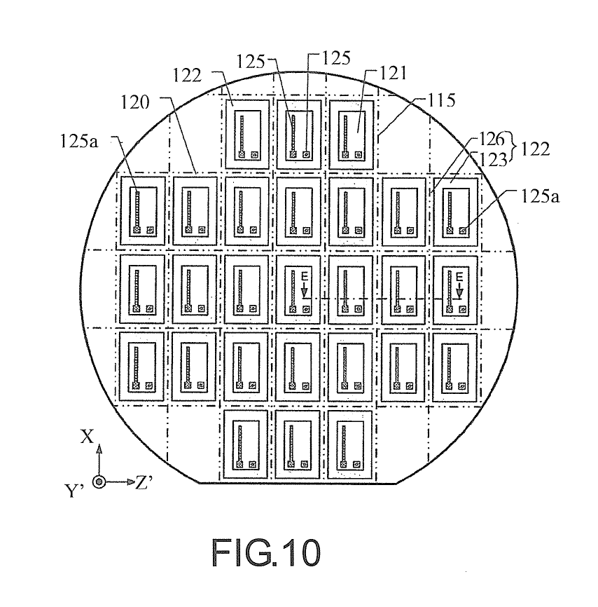

In step S102, a second wafer W120 is provided. A plurality of second plates 120 is formed on the second wafer W120. The second wafer W120 is, made of, for example, crystal or glass, etc. Description of the second wafer W120 is provided with reference of FIG. 10.

FIG. 10 is a plane view of the second wafer W120. A plurality of the second plates 120 is formed on the second wafer W120. The concave portion 121 is formed on the surface of each of the second plates 120 at the +Y′-axis. Further, the connection electrodes 125 and the through electrodes 125a are formed in the concave portion 121. A second bonding area 122 is formed at the periphery of the concave portion 121. The second bonding surface 123 enclosing the concave portion 121 is formed in the second bonding area 122, and the frame-shaped trough 126 enclosing the second bonding surface 123 is formed. In the third embodiment, the frame-shaped trough 126 is a half of the area between the second bonding surfaces 123 of two adjacent second plates 120. Further, the second bonding surface 123 is concaved to form the frame-shaped trough 126. A relationship between the frame-shaped trough 126 and the second bonding surface 123 is described with reference of FIG. 11(a)-FIG. 11(d). Further, although not illustrated in FIG. 10, the installing terminals 124 are formed on the surface of the −Y′-axis side of the second wafer W120 (referring to FIG. 7(a)). In FIG. 10, a boundary line of two adjacent second plates 120 is represented by a two-dot chain line. The two-dot chain line is the scribe line 115 used for dicing the wafer in the step S105 of FIG. 8.

In step S103, the piezoelectric vibration sheet 130 is provided. As shown in FIG. 7(a), the excitation electrodes 131 and the protrusion electrodes 132 are foimed on the piezoelectric vibration sheet 130.

In the flowchart of FIG. 8, an executing sequence of the steps S101 to S103 can be arbitrarily adjusted, or the steps S101 to S103 can be simultaneously executed.

In step S104, the piezoelectric vibration sheet 130 is disposed on the second wafer W120, and the first wafer S110 is bonded to the second wafer W120. Detailed descriptions of the step S104 are described with reference of FIG. 11(a)-FIG. 11(d).

FIG. 11(a)-FIG. 11(d) are flowcharts for describing a following process, where the process refers to the step S104 of FIG. 8, by which the piezoelectric vibration sheet 130 is disposed on the second wafer W120 and the first wafer W110 is bonded to the second wafer W120. Further, FIG. 11(a)-FIG. 11(d) used for describing the steps are presented at the right side of FIG. 11.

Referring to FIG. 11(a)-FIG. 11(d), in step S141, the piezoelectric vibration sheet 130 is disposed on the second wafer S120. The step S141 is described with reference of FIG. 11(a), and FIG. 11(a) illustrates a situation that the piezoelectric vibration sheet 130 is already disposed on the second wafer S120. Further, FIG. 11(a) is a schematic cross-sectional view of FIG. 10 along an E-E line. FIG. 11(b)-FIG. 11(d) are also schematic cross-sectional views of FIG. 10 along the same E-E line. Further, in FIG. 11(a)-FIG. 11(d), the boundary line of two adjacent second plates 120 is represented by the two-dot chain line, and the two-dot chain line is the scribe line 115, where the second wafer W120 is diced along the scribe line 115. By connecting the connection electrodes 125 with the protrusion electrodes 132 of the piezoelectric vibration sheet 130 with the conductive adhesive 151, the piezoelectric vibration sheet 130 is disposed in the concave portion 121 formed on the second plate 120 of the second wafer W120. Further, in FIG. 11(a), a relationship of the second bonding area 122, the second bonding surface 123, and the frame-shaped trough 126 of the second plate 120 is illustrated. The second bonding surface 123 is the surface of the +Y-axis side of the second plate 120 used for bonding with the first bonding surface 113 of the first plate 110. The frame-shaped trough 126 is concaved from the second bonding surface to surround the outer periphery of the second bonding surface 123. The second bonding area 122 is an area located at the +Y-axis side of the second plate 120 and including the second bonding surface 123 and the frame-shaped trough 126. The frame-shaped troughs 126 of the adjacent second plates 120 are mutually connected.

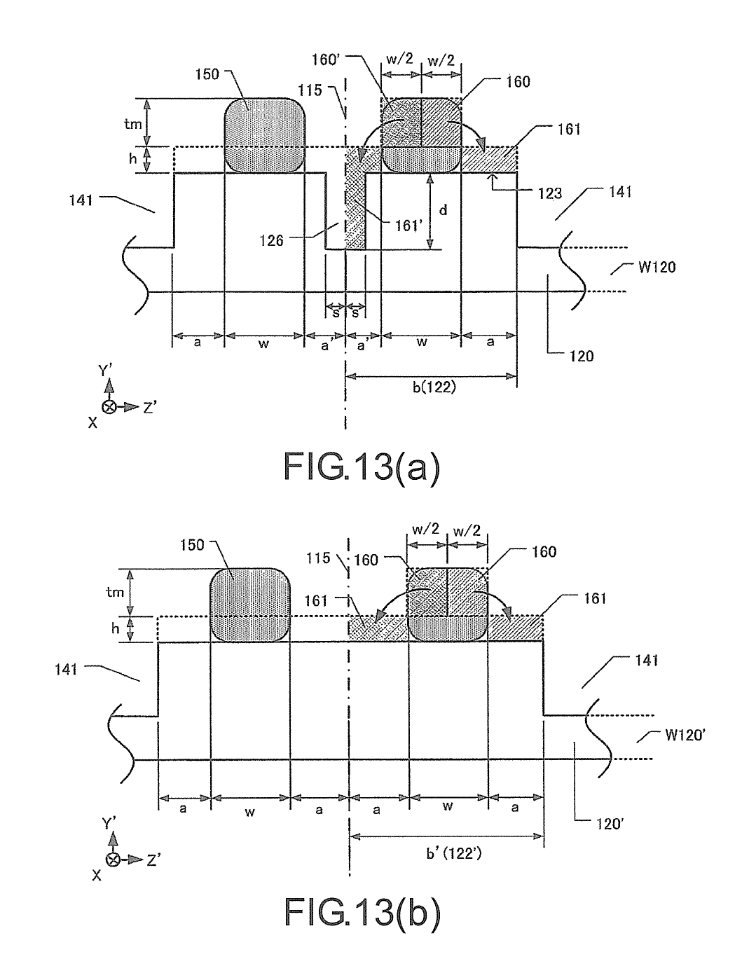

In step S142, the bonding material 150 is formed on the second bonding surface 123 of the second wafer W120. FIG. 11(b) is a cross-sectional view of the second wafer W120 formed with the bonding material 150. The bonding material 150 is, for example, a low melting point glass, and the bonding material 150 is, for example, formed on the second bonding surface 124 through screen printing. In case that the bonding material 150 is coated on the second bonding surface 123, considering that the bonding material 150 can be spread when the wafers are mutually bonded, the bonding material 150 is preferably coated on the second bonding surface 123 at a position closed to the frame-shaped trough 126. The eutectic alloy or the polyimide resin can be used as the bonding material 150 as that described in the first and the second embodiments. Moreover, the bonding material 150 has a height of tm+h (referring to FIG. 13(a) and FIG. 13(b))

In step S143, the first wafer W110 and the second wafer W120 are positioned. FIG. 11(c) illustrates a state of the first wafer W110 and the second wafer W120 before the bonding. The scribe lines 115 of the first and the second wafers W110 and W120 are overlapped along the Y′-axis direction, and the first wafer W110 and the second wafer W120 are positioned by overlapping the first boding surface 113 and the second bonding surface 123. Further, in FIG. 11(c), the first bonding area 112 is an area sandwiched between the concave portion 111 and the cut line 115.

In step S144, the first wafer W110 is pressed to bond the first wafer W110 with the second wafer W120. FIG. 11(d) illustrates a state of the first wafer W110 and the second wafer W120 after the bonding. The bonding material 150 is sandwiched between the first wafer W110 and the second wafer W120 and spreads towards the +Z′-axis direction and the −Z′-axis direction. The bonding material 150 spreading towards the frame-shaped trough 126 enters the frame-shaped trough 126. Accordingly, the height of the bonding material 150 formed between the first bonding surface 113 and the second bonding surface 123 changes from tm+h to h (referring to FIG. 13(a) and FIG. 13(b)).

Referring to FIG. 8 again, in step S105, the first wafer W110 and the second wafer W120 are diced to form a plurality of the piezoelectric devices 100. The dicing operation is performed along the scribe lines 115. If a width of the frame-shaped trough 126 is set to s (referring to FIG. 11(d)), a width of two adjacent frame-shaped troughs 126 is thereby 2s. When the width of the scribe line 115 is narrower than the total width 2s of adjacent frame-shaped troughs 126, the dicing operation is easily performed, since only the frame-shaped trough of the thinned wafer is diced. Now, the stepped portion 126a serving as a part of the frame-shaped trough 126 is formed in each of the piezoelectric device 100 (referring to FIG. 7(a) and FIG. 7(b)).

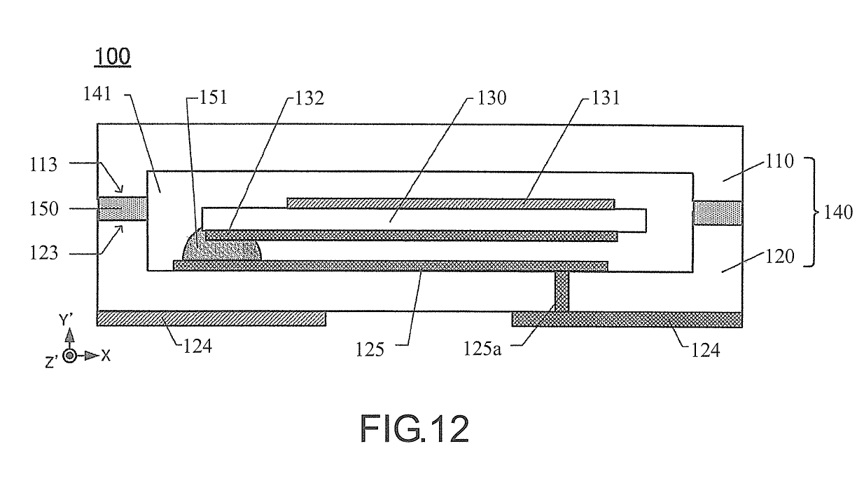

On the other hand, FIG. 12 is a cross-sectional view of the piezoelectric device 100 formed by the dicing operation when the width of the scribe line 115 is wider than the width 2s of two adjacent frame-shaped troughs 126. As shown in FIG. 12, when the step S105 of FIG. 8 is executed, i.e. the dicing operation is performed, if the width of the scribe line 115 is wider than the total width 2s of adjacent frame-shaped troughs 126, the frame-shaped trough 126 of each piezoelectric device 100 is eliminated, so as to trim the profile of the piezoelectric device 100.

<Relationship of the Bonding Material 150 and the Size of the Frame-Shaped Trough 126>

The relationship of the bonding material 150 and the size of the frame-shaped trough 126 is described with reference of FIG. 13(a) and FIG. 13(b).

FIG. 13 (a) is an enlarged schematic cross-sectional view of a part of FIG. 11(b) enclosed by a dot line 170. Before the first wafer W110 is bonded with the second wafer W120 (referring to FIG. 11(b)), the bonding material 150 has the height of tm+h. Then, the first wafer W110 is bonded to the second wafer W120 (referring to FIG. 11(d)), so that the height of the bonding material is changed to h. Further, a width of the bonding material 150 formed in FIG. 11(b) is set to w. Now, if a region with the oblique lines of the bonding material 150 of FIG. 13(a) and FIG. 13(b) is set as an initial region 160, an area of the initial region 160 is w×tm/2. Further, the bonding material 150 of the initial region 160 is moved to an extending region 161 after the first wafer W110 is bonded to the second wafer W120. If a width of the extending region 161 is a, an area of the extending region 161 is a×h. Since the area of the initial region 160 is equal to the area of the extending region 161, an expression (1) is deduced as follows:

a×h=w×tm/2 (1)

Herein, to facilitate a comparison, a situation that the frame-shaped trough 126 is not formed on the second wafer W120 is presented.

FIG. 13(b) is an enlarged schematic cross-sectional view of the second wafer W120′ without the frame-shaped trough 126. In FIG. 13(b), the same part of FIG. 11(b) enclosed by the dot line 170 is illustrated. Ideally, the bonding material 150 does not enter the cavity 141 after the first wafer W110 is bonded to the second wafer W120′. Therefore, if a width of the second bonding area 122′ is set to b′, a following expression (2) is preferably satisfied:

b′>2×a+w (2)

Further, after the expression (1) and the expression (2) are combined, a following expression (3) is deduced:

b′>w+w×tm/h=w(1tm/h) (3)

In the expression (3), the width w of the bonding material 150 is, for example, 100 μm, the height tm+h is 50 μm, and the height h of the bonding material 150 obtained after the first wafer W110 is bonded to the second wafer W120′ is 20 μm. Now, the width b′ of the second boding area 122′ is preferably greater than 250 μm.

Referring to FIG. 13(a) again, considering the situation that the frame-shaped trough 126 is formed, a depth of the frame-shaped trough 126 is set to d, a width thereof is set to s, and a distance between the scribe line 115 and the bonding material 150 is a′. When the frame-shaped trough 126 is formed, the bonding material 150 can flow into the frame-shaped trough 126 (referring to FIG. 11(d)). If the region with the hatched line of the bonding material 150 of FIG. 13(a) is set as an initial region 160′, the bonding material 150 of the initial region 160′ is moved to a hatched line region including the frame-shaped trough 126, i.e. an extending region 161′ after the first wafer W110 is bonded to the second wafer W120. If the bonding material 150 of the initial region 160′ just enters the extending region 161′, a following expression (4) is deduced:

a′×h+d×s=w×tm/2 (4)

Further, if a width of the second bonding area 122 is set to b, a following expression (5) is preferably satisfied:

b>w+a+a′ (5)

The expression (5) can be changed to a following expression (6) according to the expressions (1) and (4):

b>w×(1+tm/h)−s×d/h (6)

In the expression (6), the width w of the bonding material 150 is, for example, 100 μm, the height tm+h is 50 μm, and the height h of the bonding material 150 obtained after the first wafer W110 is bonded to the second wafer W120′ is 20 μm. Moreover, if s is set to 20 μm, and d is set to 50 μm, the width b of the second boding area 122 is preferably greater than 200 μm.

In the above example, by forming the frame-shaped trough 126, the width of the second bonding area 122 of each second plate 120 on the second wafer W120 can be narrowed to 50 μm, so that the width of each second plate 120 along the Z′-axis direction can be narrowed to 100 μm. In this way, one piece of wafer is formed, and the number of the piezoelectric devices 100 on the wafer is increased so as to reduce the manufacturing cost.

### Fourth Embodiment

In the fourth embodiment, a piezoelectric device 200 formed with a plurality of frame-shaped troughs is introduced. In the following descriptions, the elements of the piezoelectric device 200 same as or similar to those of the piezoelectric device 100 are marked with the same reference numerals and descriptions thereof are simplified or omitted.

<Formation of the Piezoelectric Device 200>

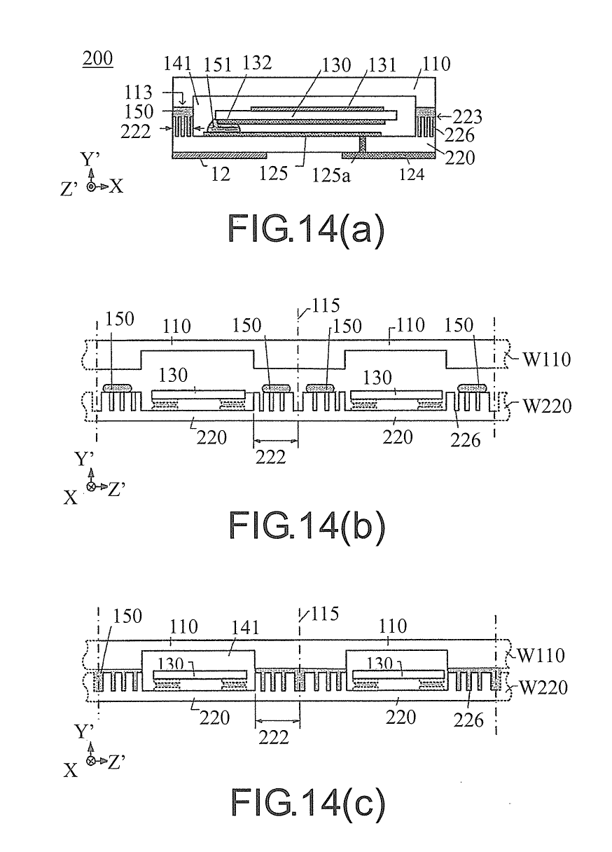

FIG. 14(a) is a cross-sectional view of the piezoelectric device 200. The piezoelectric device 200 is composed of the first plate 110, the second plate 220, the piezoelectric vibration sheet 130, and the bonding material 150. A plurality of frame-shaped troughs 226 and a plurality of second bonding surfaces 223 are formed in the bonding area 222 of the second plate 220. In the piezoelectric device 200, the bonding material 150 penetrates to at least a part of the frame-shaped troughs 226. Therefore, a contact area between the second bonding area 222 and the bonding material 150 is expanded, and the bonding of the second plate 220 and the bonding material 150 is strengthened.

A manufacturing method of the piezoelectric device 200 is the same to that of the piezoelectric device 100.

FIG. 14(b) is a schematic cross-sectional view of the first wafer W110 and the second wafer W220 before bonding. Further, FIG. 14(b) is a diagram corresponding to the step S143 of FIG. 11(a)-FIG. 11(d). In FIG. 14(b), a state that the bonding material 150 formed on the second bonding area 222 is illustrated. As shown in FIG. 14(b), the frame-shaped trough 226 has a width that the bonding material 150 does not penetrate therein.

FIG. 14(c) is a schematic cross-sectional view of the first wafer W110 and the second wafer W220 foamed with a plurality of the second plates 220 after bonding. Further, FIG. 14(c) is a diagram corresponding to the step S144 of FIG. 11(a)-FIG. 11(d). The bonding material 150 extends to the second bonding area 222 and enters the frame-shaped troughs 226. After the first wafer W110 is bonded to the second wafer W220, the bonding material 150 is prevented from penetrating into the cavity 141 since the bonding material 150 penetrates into the frame-shaped troughs 226.

### Fifth Embodiment

In the fifth embodiment, a piezoelectric device 300 formed with a frame surrounding the periphery of the piezoelectric vibration sheet is introduced. In the following descriptions, the elements of the piezoelectric device 300 same as or similar to those of the piezoelectric device 100 and the piezoelectric device 200 are marked with the same reference numerals and descriptions thereof are simplified or omitted.

<Formation of the Piezoelectric Device 300>

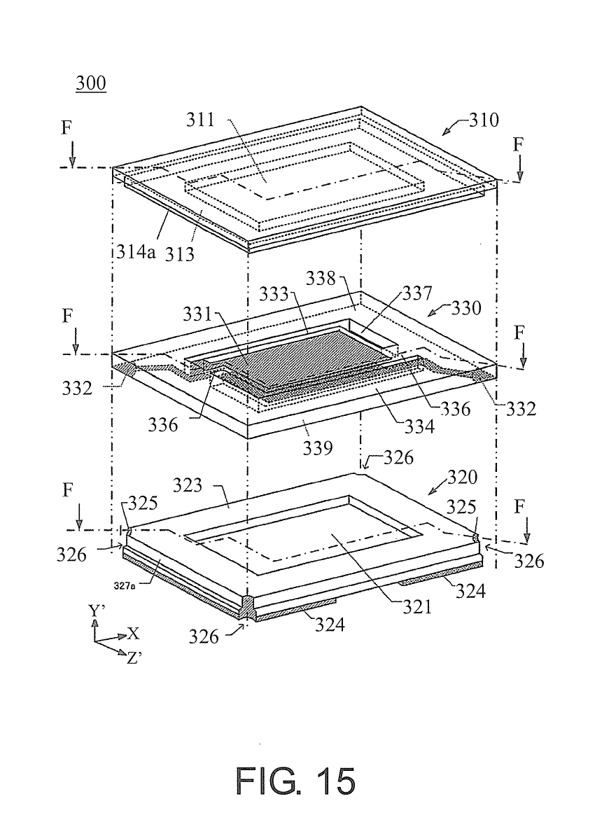

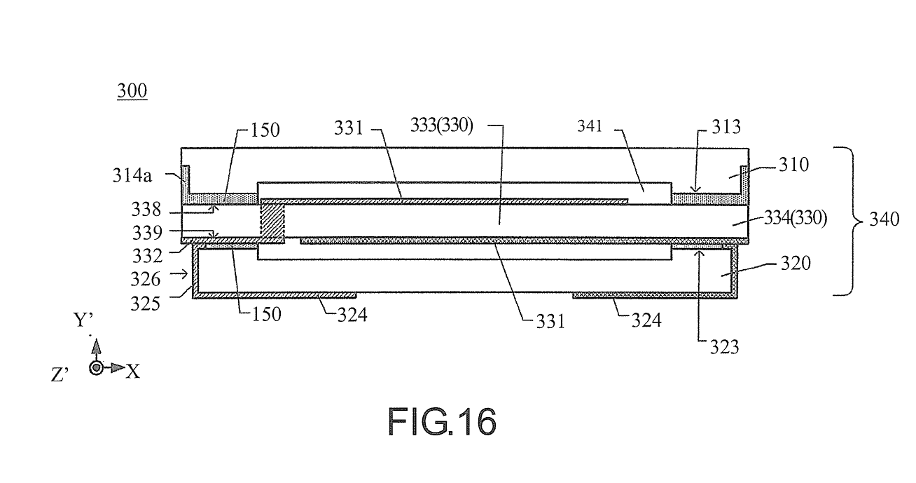

FIG. 15 is an exploded three-dimensional view of the piezoelectric device 300. The piezoelectric device 300 is composed of a first plate 310, a second plate 320, a third plate 330, and the bonding material 150 (referring to FIG. 16). The third plate 330 is composed of a piezoelectric vibration sheet 333 and a frame 334. The first plate 310, the second plate 320, and the frame 334 of the third plate 330 are bonded to form a package 340 (referring to FIG. 16), and the piezoelectric vibration sheet 333 is disposed in a cavity (referring to FIG. 16) inside the package 340.

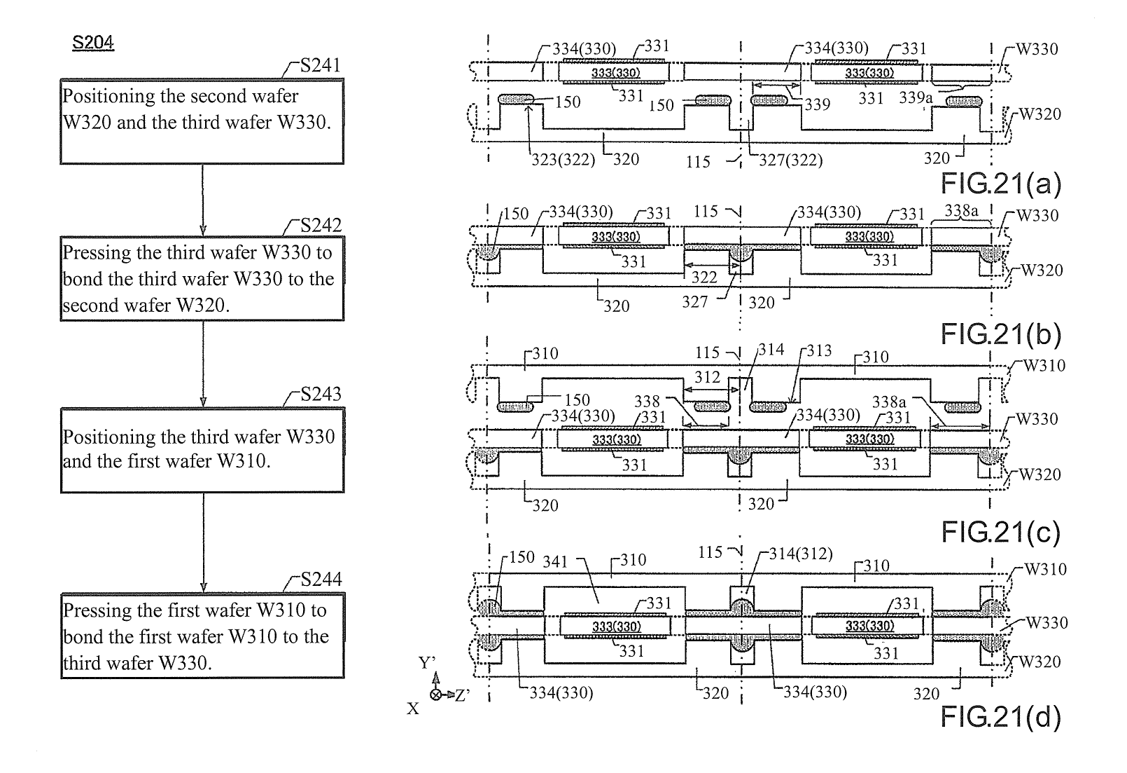

A concave portion 311 constructing a part of the cavity 341 (referring to FIG. 16) is formed on the surface of the −Y′-axis side of the first plate 310. Further, a first bonding area 312, in a shape of a frame structure, is formed to enclose the concave portion 311. In the first bonding area 312, a first bonding surface 313 used to bond a second bonding surface 323 of the second plate 320 and a stepped portion 314a serving as a part of a frame-shaped trough 314 (referring to FIG. 21(a)-FIG. 21(d) are formed. The first bonding surface 313, in a shape of a frame structure, is formed to surround the concave portion 311, and the stepped portion 314a, in a shape of a frame structure, is formed to surround the concave portion 311.

A concave portion 321 constructing a part of the cavity 341 (referring to FIG. 16) is formed on the surface of the +Y′-axis side of the second plate 320, and a second bonding surface 323, in a shape of a frame structure, is formed to enclose the concave portion 321. Further, a stepped portion 327a is formed at the outer periphery of the second bonding surface 323. Moreover, the stepped portion 327a is a part of a frame-shaped trough 327 (referring to FIG. 21(a)-FIG. 21(d)). In addition, two installing terminals 324 are formed at the surface of the −Y′-axis side of the second plate 320, and castellation structures 326 are respectively formed at corners of the fourth sides of the second plate 320. At the two corners respectively located at the −Z′-axis side, the −X-axis side and the +Z′-axis side, the +X-axis side, connection electrodes 325 are respectively formed from the installing terminal 324 to the surface of the +Y′-axis side through the castellation structure 326.

The third plate 330 is composed of the piezoelectric vibration sheet 333 and the frame 334 encircling the piezoelectric vibration sheet 333. The piezoelectric vibration sheet 333 and the frame 334 form a pair of L-shaped through-portions 337 by penetrating through the third plate 330, and connection portions 336 used for connecting the piezoelectric vibration sheet 333 and the frame 334 are formed on the third plate 330 at the place without the through-portions 337. The excitation electrodes 331 are formed on the surfaces at the +Y′-axis side and the −Y′-axis side of the piezoelectric vibration sheet 333. A protrusion electrode 332 protruded out from the excitation electrode 331 of the +Y′-axis side extends towards the −Y′-axis side of the frame 334 via the through-portion 337 till the corner at the −Z′-axis side and the −X-axis side of the frame 334. A protrusion electrode 332 protruded out from the excitation electrode 331 of the −Y′-axis side is formed at the −Y′-axis side of the frame 334, which extends to the corner at the +Z′-axis side and the +X-axis side of the frame 334 through the connection portion 336. Further, a third bonding surface 338 used to bond the first bonding surface 313 of the first plate 310 is formed on the surface of the +Y′-axis side of the frame 334, and a fourth bonding surface 339 used to bond the second bonding surface 323 of the second plate 320 is formed on the surface of the −Y′-axis side of the frame 334.

FIG. 16 is a cross-sectional view of FIG. 15 along a F-F line. The first bonding surface 313 of the first plate 310 and the third bonding surface 338 of the third plate 330 are bonded via the bonding material 150, and the second bonding surface 323 of the second plate 320 and the fourth bonding surface 339 of the third plate 330 are bonded via the bonding material 150. Further, the protrusion electrodes 332 formed on the frame 334 of the third plate 330 are electrically connected to the installing terminals 324 of the second plate 320 via the connection electrodes 325.

<Manufacturing Method of the Piezoelectric Device 300>

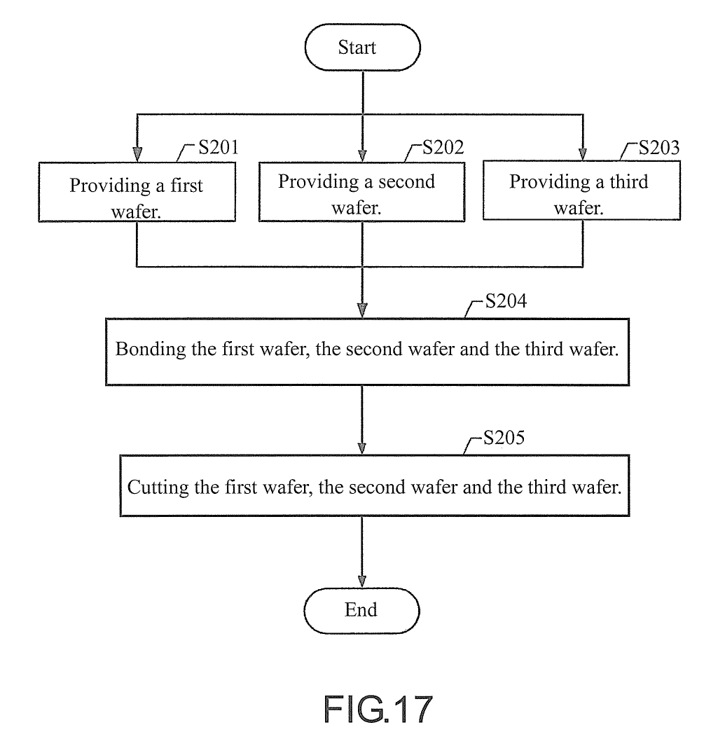

FIG. 17 is a flowchart illustrating a manufacturing method of the piezoelectric device 300.

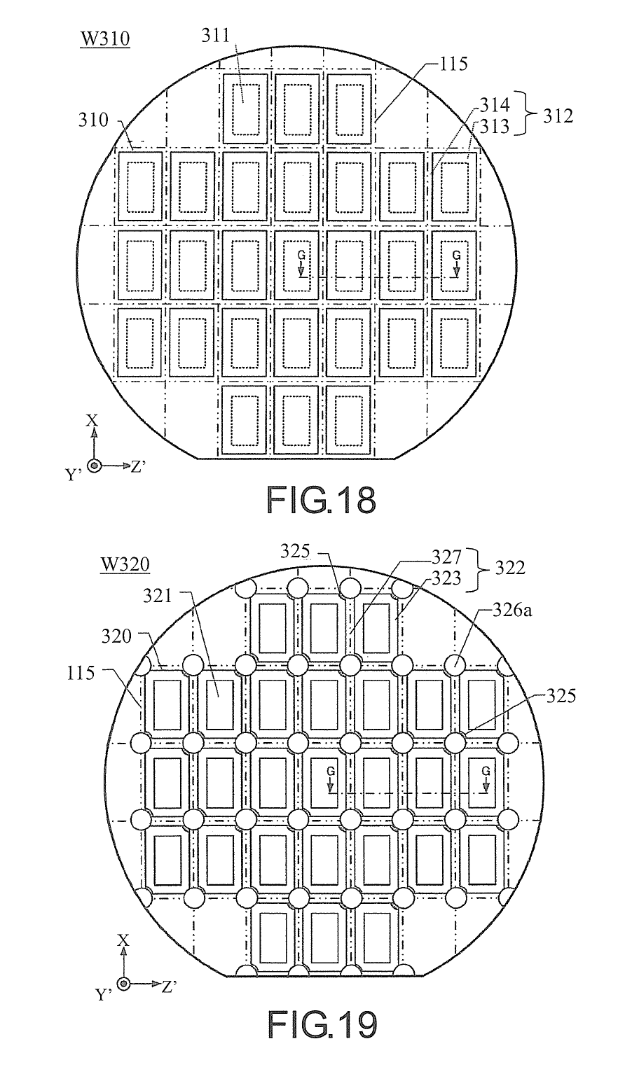

First, in step S201, the first wafer W310 is provided. A plurality of first plates 310 is formed on the first wafer W310. The first wafer W310 is, made of, for example, crystal or glass, etc. The first wafer W310 is described with reference of FIG. 18.

FIG. 18 is a plane view diagram of the first wafer W310. A plurality of the first plates 310 is formed on the first wafer W310. The surface of the +Y′-axis side of the first wafer W310 has a planar shape. Further, the concave portion 311 is formed on the surface of the −Y′-axis side of each first plate 310, and the first bonding surface 313 is formed to enclose the concave portion 311, and the frame-shaped trough 314 is formed to enclose the first bonding surface 313. Moreover, the first bonding surface 313 and the frame-shaped trough 314 are combined to form the first bonding area 312.

In step S202, the second wafer W320 is provided. A plurality of the second plates 320 is formed on the second wafer W320. The second wafer W320 is made of, for example, crystal or glass, etc. The second wafer W320 is described with reference of FIG. 19.

FIG. 19 is a plane view diagram of the second wafer W320. A plurality of the second plates 320 is formed on the second wafer W320. The concave portion 321 is formed on the surface of the +Y′-axis side of each second plate 320. Further, the second bonding surface 323 is formed at the periphery of the concave portion 321, and the frame-shaped trough 327 is formed at the periphery of the second bonding surface 323, wherein the frame-shaped trough 327 is concaved from the second bonding surface 323. Moreover, the second bonding surface 323 and the frame-shaped trough 327 are combined to form the second bonding area 322. Although not shown in FIG. 19, the installing terminals 324 (referring to FIG. 15) are formed on the surface of the −Y′-axis side of the second wafer W320. In FIG. 19, a boundary line of the adjacent second plates 320 is represented by a two-dot chain line. The two-dot chain line is the scribe line 115 used for dicing the wafer in a step 205 of FIG. 17. Moreover, through-holes 326a penetrating through the second wafer W320 are formed at intersections of the scribe lines 115 extending along the Z′-axis direction and the X-axis direction. The through-holes 326a are used to form the castellation structures 326 (referring to FIG. 15) after the wafer is diced. The connection electrodes 325 are formed in the through-holes 326a.

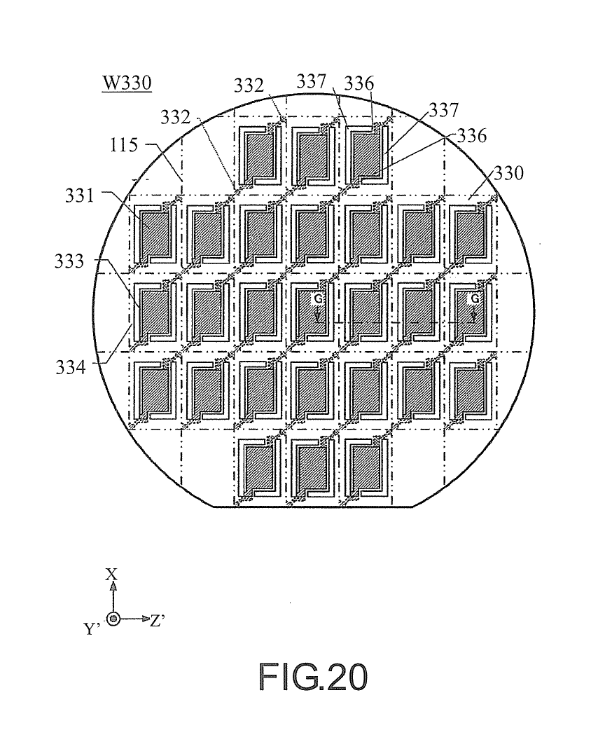

In step S203, the third wafer W330 is provided. A plurality of the third plates W330 is formed on the third wafer W330. The third wafer W330 is described with reference of FIG. 20.

FIG. 20 is a plane view diagram of the third wafer W330. A plurality of the third plates 330 is formed on the second wafer W330. Each of the third plates 330 is composed of the piezoelectric vibration sheet 333 and the frame 334 surrounding the piezoelectric vibration sheet 333. The piezoelectric vibration sheet 333 and the frame 334 are separated by the L-shape through-portions 337, and the connection portions 336 used for connecting the piezoelectric vibration sheet 333 and the frame 334 are formed on the third plate 330 at the place without the through-portions 337. The excitation electrodes 331 are formed on the piezoelectric vibration sheet 333. Further, the protrusion electrodes 332 extend from the excitation electrodes 331 to the corners of the frame 334 through the connection portions 336.

In the flowchart of FIG. 17, an executing sequence of the steps S201 to S203 can be arbitrarily adjusted, or the steps S201 to S203 can be simultaneously executed.

In step S204, the third wafer W330 and the second wafer W320 are bonded, and the first wafer W310 and the second wafer W320 are bonded. The step S204 is described in detail with reference of FIG. 21(a)-FIG. 21(d).

FIG. 21(a)-FIG. 21(d) are flowcharts for describing a bonding process, where the bonding process refers to the step S204 of FIG. 17, by which the first wafer W310, the second wafer W320, and the third wafer W330 are bonded. Further, FIG. 21(a)-FIG. 21(d) used for describing the steps are presented at the right side of FIG. 21.

In FIG. 21(a)-FIG. 21(d), first, in step S241, the second wafer W320 and the third wafer W330 are positioned. The step S241 is described with reference of FIG. 21(a). FIG. 21(a) is a cross-sectional view of the third wafer W330 and the second wafer W320 before bonding. FIG. 21(a)-FIG. 21(d) are schematic cross-sectional views of FIG. 18-FIG. 20 along a G-G line. Further, in FIG. 21(a)-FIG. 21(d), the boundary line of adjacent second plates 320 is represented by a two-dot chain line, and the two-dot chain line represents the scribe line 115. In FIG. 21(a), the second bonding area 322 including the second bonding surface 323 and the frame-shaped trough 327 concaved from the second bonding surface 323 are illustrated. Further, the fourth bonding area 339a, i.e. the surface of the −Y′-axis side of the frame 334 of the third wafer W330 is illustrated. The fourth bonding area 339a includes the fourth bonding surface 339 used for bonding the second bonding surface 323 of the second wafer W320. The second wafer W320 and the third wafer W330 are positioned by overlapping the respective scribe lines 115 and overlapping the second bonding surface 323 and the fourth bonding surface 339 formed on the fourth bonding area 339a.

In step S242, the third wafer W330 is pressed to bond the third wafer W330 to the second wafer W320. FIG. 21(b) illustrates a state that the third wafer W330 is bonded to the second wafer W320. By pressing the third wafer W330 to bond with the second wafer W320, the bonding material 150 extends towards the +Z′-axis direction and the −Z′-axis direction. The bonding material 150 extending towards the outer periphery of the second plate 320 enters the frame-shaped trough 327.

In step S243, the third wafer W330 and the first wafer W310 are positioned. After forming the bonding material on the first bonding surface 323 of the first wafer W310, the first and the third wafers W310 and W330 are positioned. FIG. 21(c) is a cross-sectional view of the first wafer W310 and the third wafer W330 before bonding. In FIG. 21(c), the first bonding area 312 including the first bonding surface 313 and the frame-shaped trough 314 concaved from the first bonding surface 313 are illustrated. Further, a third bonding area 338a, i.e. the surface of the +Y′-axis side of the frame 334 of the third wafer W330 is illustrated. The third bonding area 338a includes the third bonding surface 338 used for bonding the first bonding surface 313 of the first wafer W310. The first wafer W310 and the third wafer W330 are positioned by overlapping the respective scribe lines 115 and overlapping the first bonding surface 313 of the first wafer W310 and the third bonding surface 338 of the third wafer W330.

In step S244, the first wafer W310 is pressed to bond the first wafer W310 to the third wafer W330. FIG. 21(d) illustrates a state that the first wafer W310 is bonded to the third wafer W330. By bonding the first wafer W310 to the third wafer W330, the sealed cavity 341 is formed therebetween. By pressing the third wafer W330 to bond with the first wafer W310, the bonding material 150 spreads towards the +Z′-axis direction and the −Z′-axis direction. The bonding material 150 spreading towards the outer periphery of the first plate 310 penetrates into the frame-shaped trough 314.

Referring to FIG. 17 again, in step S205, the first wafer W310, the second wafer W320, and the third wafer W330 bonded in the step S204 are diced along the scribe lines 115 represented by the two-dot chain lines shown in FIG. 18-FIG. 20.

Regarding the piezoelectric device 300, as described above, since the first wafer W310 and the second wafer W320 have the frame-shaped trough 314 and the frame-shaped trough 327, the bonding material 150 is prevented from penetrating into the cavity 341. Moreover, as shown in FIG. 13(a), in the piezoelectric device 300, widths of the first bonding area 312 of the first wafer W310 and the second bonding area 322 of the second wafer W320 can be narrowed, so that the number of the piezoelectric devices 300 formed on the wafer can be increased. In addition, in the piezoelectric device 300, the frame-shaped troughs are formed on the first wafer W310 and the second wafer W320, though the frame-shaped trough can also be formed on the frame 334 of the third wafer W330. Moreover, regarding the frame-shaped trough, as shown in FIG. 14(a)-FIG. 14(c), a plurality of the frame-shaped troughs can be formed on one piezoelectric device 300. The frame-shaped troughs can be formed on at least one of the first to the fourth bonding surfaces. Moreover, similar to the piezoelectric device 100, if the whole width of the frame-shaped trough is narrower than that of the scribe line 115, the frame-shaped trough is not fanned on each of the piezoelectric devices 300, so as to trim the profile of the piezoelectric device 300 (referring to FIG. 12). Moreover, if the whole width of the scribe line is narrower than the width of the frame-shaped trough, the dicing operation is easily performed since only the frame-shaped trough of the thinned wafer is diced.

Exemplary embodiments of the invention have been described above, though those skilled in the art can perform various modifications and variations to the structure of the present invention without departing from the scope or spirit of the invention.

For example, although the piezoelectric vibration device is implemented by the AT-cut crystal vibration device, a BT-cut vibration device vibrated in a thickness shear mode can also be used. Moreover, a tuning fork crystal vibration device can also be applied. In addition, the piezoelectric vibration device not only can apply to the crystal material, it can also apply to the piezoelectric material including lithium tantalate or lithium niobate or piezoelectric ceramic.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A piezoelectric device, comprising a piezoelectric vibration sheet vibrated by applying a voltage, and the piezoelectric device comprising:
a first plate, constructing a first part of a package of the piezoelectric device, and having a first bonding area that includes a frame-shaped first bonding surface at an outer periphery;
a second plate, constructing a second part of the package of the piezoelectric device, and having a second bonding area that includes a second bonding surface corresponding to the first bonding surface; and
a frame-shaped bonding material, formed on the first bonding surface and the second bonding surface, for bonding the first plate and the second plate,
a frame-shaped trough concave from the first bonding surface or the second bonding surface configured in at least one of the first bonding area of the first plate or the second bonding area of the second plate.

2. A piezoelectric device, comprising a piezoelectric vibration sheet vibrated by applying a voltage, and the piezoelectric device comprising:
a first plate, constructing a first part of a package of the piezoelectric device, and having a first bonding area that includes a frame-shaped first bonding surface at an outer periphery;
a second plate, constructing a second part of the package of the piezoelectric device, and having a second bonding area that includes a frame-shaped second bonding surface at the outer periphery;
a third plate, composed of the piezoelectric vibration sheet and a frame enclosing the piezoelectric vibration sheet, wherein the frame has a third bonding area including a third bonding surface corresponding to the first bonding surface and a fourth bonding area including a fourth bonding surface located at an opposite side of the third bonding surface and corresponding to the second bonding surface; and
a frame-shaped bonding material, formed on the first bonding surface, the second bonding surface, the third bonding surface, and the fourth bonding surface, for bonding the first plate and the third plate and bonding the second plate and the fourth plate,
a frame-shaped trough concave from the first bonding surface, the second bonding surface, the third bonding surface, or the fourth bonding surface configured in at least one of the first bonding surface and the third bonding surface and at least one of the second bonding surface and the fourth bonding surface.

3. The piezoelectric device as claimed in claim 1, wherein at least a part of the frame-shaped bonding material penetrates into the frame-shaped trough.

4. The piezoelectric device as claimed in claim 2, wherein at least a part of the frame-shaped bonding material penetrates into the frame-shaped trough.

5. The piezoelectric device as claimed in claim 1, wherein the frame-shaped trough comprises a stepped portion with a sidewall formed in at least one direction, and the stepped portion is formed at an outermost periphery of the piezoelectric device.

6. The piezoelectric device as claimed in claim 2, wherein the frame-shaped trough comprises a stepped portion with a sidewall formed in at least one direction, and the stepped portion is formed at an outermost periphery of the piezoelectric device.

7. The piezoelectric device as claimed in claim 1, wherein the frame-shaped trough comprises a plurality of troughs, and the troughs are fon led at an inner side of the frame-shaped bonding material and at a bonding surface side of the frame-shaped bonding material.

8. The piezoelectric device as claimed in claim 2, wherein the frame-shaped trough comprises a plurality of troughs, and the troughs are formed at an inner side of the frame-shaped bonding material and at a bonding surface side of the frame-shaped bonding material.

9. The piezoelectric device as claimed in claim 1, wherein a frame-shaped metal film is formed under the frame-shaped bonding material, and the frame-shaped bonding material is a eutectic alloy.

10. The piezoelectric device as claimed in claim 2, wherein a frame-shaped metal film is formed under the frame-shaped bonding material, and the frame-shaped bonding material is a eutectic alloy.

11. The piezoelectric device as claimed in claim 9, wherein the frame-shaped metal film is formed on an inner bottom surface of the frame-shaped trough.

12. The piezoelectric device as claimed in claim 11, wherein a width of the frame-shaped metal film is narrower than a width of the frame-shaped trough.

13. The piezoelectric device as claimed in claim 9, wherein the frame-shaped trough is disposed in at least an inner side of the frame-shaped metal film.

14. The piezoelectric device as claimed in claim 13, wherein a metal film is disposed on the inner bottom surface of the frame-shaped trough.

15. A manufacturing method of a piezoelectric device, wherein the piezoelectric device has a piezoelectric vibration sheet vibrated by applying a voltage, and the manufacturing method of the piezoelectric device comprising:
providing a first wafer comprising a plurality of first plates in a first preparation step, wherein the first plates construct a first part of a package of the piezoelectric device and have a frame-shaped first bonding surface at an outer periphery;
providing a second wafer comprising a plurality of second plates in a second preparation step, wherein the second plates construct a second part of the package of the piezoelectric device and have a second bonding surface corresponding to the first bonding surface;
performing a bonding step by using a bonding material, in a shape of a frame structure, formed on the first bonding surface or the second bonding surface to bond the first wafer and the second wafer; and
performing a dicing step by using a scribe line to dice the bonded first wafer and the second wafer,
wherein at least one of the first preparation step and the second preparation step is performed and at least a part of the scribe line is included to form a frame-shaped trough concave from the first bonding surface or the second bonding surface at the outer periphery of the first plate or the second plate, and
the bonding step is performed to introduce the bonding material into at least a part of the frame-shaped trough.

16. A manufacturing method of a piezoelectric device, wherein the piezoelectric device has a piezoelectric vibration sheet vibrated by applying a voltage, and the manufacturing method of the piezoelectric device comprising:
providing a first wafer comprising a plurality of first plates in a first preparation step, wherein the first plates construct a first part of a package of the piezoelectric device and have a frame-shaped first bonding surface at an outer periphery;
providing a second wafer comprising a plurality of second plates in a second preparation step, wherein the second plates construct a second part of the package of the piezoelectric device and have a second bonding surface at the outer periphery;
providing a third wafer comprising a plurality of third plates in a third preparation step, wherein the third plates comprise a plurality of the piezoelectric vibration sheets and a plurality of frames respectively enclosing the piezoelectric vibration sheets, wherein each frame of the plurality of frames has a third bonding surface corresponding to the first bonding surface and a fourth bonding surface located at an opposite side of the third bonding surface and corresponding to the second bonding surface;
performing a bonding step by using a bonding material, in a shape of a frame structure, formed on the first bonding surface, the second bonding surface, the third bonding surface, or the fourth bonding surface to bond the first wafer and the second wafer with the third wafer in between; and
performing a dicing step by applying a scribe line to diced the bonded first wafer, the second wafer, and the third wafer,
wherein at least one of the first preparation step, the second preparation step, and the third preparation step is performed and at least a part of the scribe line is included to form a frame-shaped trough concave from the first bonding surface, the second bonding surface, the third bonding surface, or the fourth bonding surface of the first plate, the second plate, or the third plate, and
the bonding step is performed to introduce the bonding material into at least a part of the frame-shaped trough.

17. The manufacturing method of the piezoelectric device as claimed in claim 15, wherein the frame-shaped trough comprises a plurality of troughs, and the plurality of troughs is formed at an inner side of the bonding material and at a bonding surface side of the bonding material.

18. The manufacturing method of the piezoelectric device as claimed in claim 16, wherein the frame-shaped trough comprises a plurality of troughs, and the plurality of troughs is formed at an inner side of the bonding material and at a bonding surface side of the bonding material.

19. The manufacturing method of the piezoelectric device as claimed in claim 15, wherein the frame-shaped trough comprises the scribe line, and a width of the frame-shaped trough including the scribe line is narrower than a width of the scribe line.

20. The manufacturing method of the piezoelectric device as claimed in claim 16, wherein the frame-shaped trough comprises the scribe line, and a width of the frame-shaped trough including the scribe line is narrower than a width of the scribe line.
